(19) United States
(12) Patent Application Publication
(10) Pub. No.: US 2024/0230567 A1
(43) Pub. Date: Jul. 11, 2024

(54) ACTIVE VOLUME IMAGING

(71) Applicant: Navix International Limited, Tortola (VG)

(72) Inventors: Shlomo BEN-HAIM, Milan (IT); Andrew ADLER, Ottawa (CA); Bartlomiej GRYCHTOL, Den Haag (NL)

(73) Assignee: Navix International Limited, Tortola (VG)

(21) Appl. No.: 18/404,949

(22) Filed: Jan. 5, 2024

Related U.S. Application Data
(60) Provisional application No. 63/437,140, filed on Jan. 5, 2023.

(51) Int. Cl. G01N 27/04; G01N 27/327; G01R 27/16

(52) U.S. Cl. CPC G01N 27/041; G01N 27/045; G01N 27/3273; G01R 27/16

(57) ABSTRACT

Methods and apparatuses for imaging an intra-body object. An exemplary method includes: measuring electrical measurements using electrodes of a probe hovering inside a body lumen; identifying, based on said electrical measurements, a volume encompassing the electrodes used for the measurements as a volume free of any lumen wall; and inferring, from the identified volume free of any lumen wall, a wall in the vicinity of the probe, thereby imaging at least a portion of the object.

### RELATED APPLICATIONS

This application claims the benefit of priority of U.S. Provisional Patent Application No. 63/437,140 filed on Jan. 5, 2023, the contents of which are incorporated herein by reference in their entirety.

### FIELD AND BACKGROUND OF THE INVENTION

The present invention, in some embodiments thereof, relates to the field of imaging within body cavities by intra-body devices (for example: multi-electrode probes); and more particularly, to imaging using electrical fields generated and sensed inside the body.

Intra-body imaging is useful for accompanying many catheterization processes, including, but not limited to, minimally invasive structural heart disease interventions.

One such imaging method is described in International Patent Publication No. WO2019/035023.

### SUMMARY OF THE INVENTION

According to an aspect of some embodiments of the present disclosure, there is provided a method of estimating a proximity of a wall of an intra-body lumen to a first electrode at a first position within the body lumen, the method including: generating an electrical field by transmitting a current from the first electrode to a ground electrode; measuring a voltage difference of the electrical field between the first electrode and a second electrode at a second position within the body lumen; calculating a measure of local impedance for a region around the first electrode, using: the voltage difference measured between the first and second electrodes and a measurement of the current between the first electrode and the ground; and converting the measure of local impedance to an estimate of proximity of the wall of the intra-body lumen to the first electrode.

According to some embodiments of the present disclosure, the measure of local impedance is proportional to the voltage difference between the first and second electrodes.

According to some embodiments of the present disclosure, the measure of local impedance is inversely proportional to an amount of current transmitted from the first electrode.

According to some embodiments of the present disclosure, less than 10% of current flowing from the first electrode flows through the second electrode.

According to some embodiments of the present disclosure, the ground electrode is at least 5 cm away from each of the first and second electrodes.

According to some embodiments of the present disclosure, the ground electrode and the first and second electrodes are all on the same probe.

According to some embodiments of the present disclosure, the measure of local impedance is at least 5× more sensitive to the wall at a distance of 5 mm from the first electrode than at a distance of 5 mm from the second electrode.

According to some embodiments of the present disclosure, the method also comprises the generating, measuring, calculating, and converting as recited for the first electrode and second electrode, with the first electrode in roles as recited for the second electrode and the second electrode in roles as recited for the first electrode, wherein the first and second electrodes transmit their respective currents at different respective frequencies.

According to some embodiments of the present disclosure, the current transmitted from the first electrode to the ground electrode is restricted from flowing through the second electrode by an impedance at least ten times larger than the impedance between the first electrode and the ground electrode.

According to some embodiments of the present disclosure, the converting includes applying a sensitivity function describing the measure of local impedance as a function of distance to a nearest wall portion.

According to some embodiments of the present disclosure, the sensitivity function is determined based on a distance between the first and second electrodes, with the sensitivity range increasing as the distance becomes larger.

According to some embodiments of the present disclosure, the method includes repeating the voltage measuring, calculating, and converting to produce a plurality of estimates of proximity of the wall for each of a corresponding plurality of positions of the first electrode; and including mapping a shape of the wall, using the estimated proximity of the wall in each of the plurality of positions of the first electrode.

According to some embodiments of the present disclosure, the mapping includes: defining an array of voxels representing volumes of a three-dimensional space; for each estimate of the proximity of the wall to the first electrode, accumulating evidence of presence of a wall within a substantially spherical shell region represented by some voxels of the array of voxels; wherein the shell region is centered on a position of the first electrode, and has a radius corresponding to the estimate of the proximity of the wall to the first electrode.

According to some embodiments of the present disclosure, the shell region has a predetermined thickness.

According to some embodiments of the present disclosure, the mapping includes analyzing a distribution of wall presence evidence accumulated in the array of voxels, to determine positions of the wall consistent with the accumulated wall presence evidence.

According to some embodiments of the present disclosure, the mapping includes for each estimate of the proximity of the wall, accumulating evidence of absence of a wall within a substantially spherical region represented by some voxels of the array of voxels; wherein the spherical region is centered on a position of the first electrode, and has a radius corresponding to the estimate of the proximity of the wall and the first electrode.

According to some embodiments of the present disclosure, the converting includes comparing the measure of local impedance to a local impedance measured while the first electrode is located at least 10 mm away from any wall of the intra-body lumen.

According to some embodiments of the present disclosure, the method includes performing the generating, the measuring, and the calculating while the first electrode is at a first position at least 10 mm away from the wall, and then while the first electrode is at a second position between 5 and 9 mm away from the wall; and wherein the estimating of the second position between 5 and 9 mm away from the wall is performed without using measurements obtained by the first electrode at a position less than 5 mm away from the wall.

According to an aspect of some embodiments of the present disclosure, there is provided a method of estimating a location of a wall of an intra-body lumen, the wall being within an examined region including a plurality of examined locations, and the method including: for each of a plurality of reference positions within the intra-body lumen: measuring a wall distance-indicating parameter associated with the respective reference position, and calculating a respective wall-presence evidence value for each of a respective multiplicity of the plurality of examined locations, using the measurements of the distance-indicating parameter; wherein the measuring a wall distance-indicating parameter includes: generating an electrical field by transmitting a current from a first electrode to a ground electrode; measuring a voltage difference of the electrical field between the first electrode and a second electrode at a second position within the body lumen; calculating a measure of local impedance for a region around the first electrode, using: the voltage difference measured between the first and second electrodes and a measure of the current between the first electrode and the ground electrode; and converting the measure of local impedance to an estimate of proximity of the wall of the intra-body lumen to the first electrode.

According to some embodiments of the present disclosure, the method includes: for each of the plurality of examined locations: cumulating respective wall-presence evidence values to obtain a respective wall-presence likelihood value, and associating the obtained respective wall-presence likelihood value to the respective examined location; and estimating a shape and a location of the wall within the examined region, based on the plurality of examined locations and their respective wall-presence likelihood values.

According to some embodiments of the present disclosure, the parameter indicative of distance between the wall and the reference position is derived from the measured voltage difference and the measure of the current, measured while the electrode occupies the reference position to which the value of the parameter is associated.

According to some embodiments of the present disclosure, the value is measured using a probe including the first electrode and the second electrode.

According to some embodiments of the present disclosure, the ground electrode is placed at least 5 cm from the first electrode.

According to some embodiments of the present disclosure, the estimating estimates the location of the wall based on examined locations associated with wall-presence likelihood values beyond a minimum likelihood.

According to some embodiments of the present disclosure, the method further includes, for each respective examined location: cumulating likelihood values for blood presence using location-associated blood evidence values calculated using the measurements of the distance-indicating parameter and their associated positions; wherein the estimating uses the likelihood values for blood presence to help determine which of the plurality of examined locations with a cumulated wall-presence likelihood value is actually a non-wall location.

According to some embodiments of the present disclosure, the estimating uses the likelihood values for blood presence to override wall-presence likelihood values.

According to some embodiments of the present disclosure, the estimating estimates an examined location to be a wall location based on the examined location having a respective wall-presence likelihood value beyond a minimum likelihood, and a respective predetermined likelihood value for blood-presence within a predetermined likelihood.

According to some embodiments of the present disclosure, the first electrode is one of a plurality of electrodes of a probe positioned within the intra-body lumen, wherein each electrode of the plurality of electrodes is also used as the first electrode to separately measure values of the distance-indicating parameter at different positions of the electrodes.

According to some embodiments of the present disclosure, the calculating includes treating the measurements of the distance-indicating parameter by each of the plurality of electrodes of the probe as contributors to the wall-presence likelihood values for wall presence.

According to some embodiments of the present disclosure, estimating the location of the wall includes estimating a shape of the wall over an extended portion of 3-D space.

According to some embodiments of the present disclosure, estimating the location of the wall includes identifying some of the plurality of examined locations as wall locations.

According to some embodiments of the present disclosure, wall-presence evidence values calculated using values of the distance-indicating parameter larger than a distance threshold are not cumulated for any examined location.

According to some embodiments of the present disclosure, the distance threshold is selected based on an estimated distance limit within which the first electrode is sensitive to presence of the wall.

According to some embodiments of the present disclosure, the distance threshold is larger than about 8-10 mm.

According to some embodiments of the present disclosure, the method further includes: estimating a minimum distance of the wall from each reference position, based on the measurement of the distance-indicating parameter; wherein the wall-presence likelihood values are obtained by cumulating wall-presence evidence values only for a plurality of pairs, wherein each pair includes a reference position as a first member of the pair and an examined location as a second member of the pair, the first and second members of the pair being separated by at least the estimated minimum distance.

According to some embodiments of the present disclosure, for each of the plurality of reference positions, each of the respective multiplicity of the plurality of examined locations is separated from the respective reference position by at least the minimum distance.

According to some embodiments of the present disclosure, the minimum distance is between about 8 and about 10 mm.

According to some embodiments of the present disclosure, the cumulating cumulates wall-presence evidence values only for pairs including a reference position and an examined location separated by no more than the minimum distance plus a predetermined thickness.

According to some embodiments of the present disclosure, the predetermined thickness is within a range of 1.8-2.2 mm.

According to some embodiments of the present disclosure, the wall-presence evidence value decreases monotonically with increasing distance from the minimum distance.

According to some embodiments of the present disclosure, the wall-presence evidence remains constant with increasing distance from the minimum distance to the distance of the minimum distance plus the thickness.

According to some embodiments of the present disclosure, the wall-presence evidence value varies with distance from the respective reference position at least when the distance is larger than the minimum distance and less than the minimum distance plus the thickness.

According to some embodiments of the present disclosure, the distance-indicating value is indicative of the same distance to the wall in all directions.

According to some embodiments of the present disclosure, the distance-indicating value is indicative of distance from the reference position to the wall.

According to some embodiments of the present disclosure, the value associated with each position of the plurality of reference positions is a value measured using the first electrode when the first electrode was in the position.

According to some embodiments of the present disclosure, the cumulating is restricted to cumulate blood-presence evidence values only when the examined location is within an estimated minimum distance to the wall from the reference position, the estimated minimum distance being calculated based on the value of the distance-indicating parameter associated with the reference position.

According to some embodiments of the present disclosure, blood-presence evidence is accumulated for a measured value of the distance-indicating parameter with values varying as a function of distance from the reference position.

According to some embodiments of the present disclosure, blood-presence evidence is accumulated for a measured value of the distance-indicating parameter with the same value in all directions from the reference position associated with the value.

According to some embodiments of the present disclosure, blood-presence evidence is accumulated for a measured value of the distance-indicating parameter with values decreasing function of distance from the reference position.

According to an aspect of some embodiments of the present disclosure, there is provided a system including a processor and memory, the memory storing instructions which instruct the processor to perform the calculating and the converting according to any of the methods described above.

According to some embodiments of the present disclosure, the memory stores instructions which further instruct the processor to generate an image showing a shape of the wall of the intra-body lumen determined from the calculating and converting, and provide it to be presented by the display.

According to an aspect of some embodiments of the present disclosure, there is provided a system including a processor and memory, the memory storing instructions which instruct the processor to perform any of the methods described above.

According to an aspect of some embodiments of the present disclosure, there is provided a system for estimating a proximity of a wall of an intra-body lumen to a first electrode at a first position within the intra-body lumen, the system including: a ground electrode; at least one probe sized and configured to be positioned in the intra-body lumen, the at least one probe including the first electrode and at least a second electrode; a parameter measuring device, configured to generate an electrical field by transmitting a current from the first electrode to a ground electrode; a measuring device, configured to measure the current, and to measure a voltage difference of the electrical field between the first electrode and the second electrode, the second electrode being positioned at a second position within the intra-body lumen; a processor and a memory storing processor instructions, wherein the processor instructions instruct the processor to calculate a measure of local impedance for a region around the first electrode, using: the voltage difference measured between the first and second electrodes, and the measured current between the first electrode and the ground electrode.

According to some embodiments of the present disclosure, the processor instructions further instruct the processor to convert the measure of local impedance to an estimate of proximity of the wall of the intra-body lumen to the first electrode.

According to some embodiments of the present disclosure, the measure of local impedance is at least 5× more sensitive to the wall at a distance of 5 mm from the first electrode than at a distance of 5 mm from the second electrode.

According to some embodiments of the present disclosure, the processor also is instructed to calculate and convert as recited for the first electrode and second electrode, with the first electrode in roles as recited for the second electrode and the second electrode in roles as recited for the first electrode; wherein the first and second electrodes transmit their respective currents at different respective frequencies.

According to some embodiments of the present disclosure, the processor applies a sensitivity function describing the measure of local impedance as a function of distance to a nearest wall portion to convert the measure of local impedance to the estimate of proximity.

According to some embodiments of the present disclosure, the sensitivity function is determined based on a distance between the first and second electrodes, with the sensitivity range increasing as the distance becomes larger.

According to some embodiments of the present disclosure, the system is configured to repeat the voltage measuring, the calculation, and the conversion, to produce a plurality of estimates of proximity of the wall for each of a corresponding plurality of positions of the first electrode; and the instruction instruct the processor to map a shape of the wall, using the estimated proximity of the wall in each of the plurality of positions of the first electrode.

According to some embodiments of the present disclosure, the processor is instructed to map the shape of the wall by: defining an array of voxels representing volumes of a three-dimensional space; and for each estimate of the proximity of the wall to the first electrode, accumulating evidence of presence of a wall within a substantially spherical shell region represented by some voxels of the array of voxels; wherein the shell region is centered on a position of the first electrode, and has a radius corresponding to the estimate of the proximity of the wall to the first electrode.

According to some embodiments of the present disclosure, the shell region has a predetermined thickness.

According to some embodiments of the present disclosure, the processor is instructed to map the shape of the wall by analyzing a distribution of wall presence evidence accumulated in the array of voxels, to determine positions of the wall consistent with the accumulated wall presence evidence.

According to some embodiments of the present disclosure, the processor is instructed to map the shape of the wall by: for each estimate of the proximity of the wall, accumulating evidence of absence of a wall within a substantially spherical region represented by some voxels of the array of voxels; wherein the spherical region is centered on a position of the first electrode, and has a radius corresponding to the estimate of the proximity of the wall and the first electrode.

According to some embodiments of the present disclosure, the processor is instructed to perform the conversion by comparing the measure of local impedance to a local impedance measured while the first electrode is located at least 10 mm away from any wall of the intra-body lumen.

According to some embodiments of the present disclosure, the processor is instructed to calculate the measure of local impedance using a measurement measured while the first electrode is at a first position at least 10 mm away from the wall, and another measurement measured while the first electrode is at a second position between 5 and 9 mm away from the wall; and to estimate of the second position between 5 and 9 mm away from the wall without using measurements obtained by the first electrode at a position less than 5 mm away from the wall.

According to some embodiments of the present disclosure, the measure of local impedance is proportional to the voltage difference between the first and second electrodes.

According to some embodiments of the present disclosure, the measure of local impedance is inversely proportional to an amount of current transmitted from the first electrode.

According to some embodiments of the present disclosure, less than 10% of current flowing from the first electrode flows through the second electrode.

According to some embodiments of the present disclosure, the ground electrode is configured to be positioned at least 5 cm away from each of the first and second electrodes.

According to some embodiments of the present disclosure, the ground electrode and the first and second electrodes are all on the same probe of the at least one probe.

According to some embodiments of the present disclosure, the current transmitted from the first electrode to the ground electrode is restricted from flowing through the second electrode by an impedance at least ten times larger than the impedance between the first electrode and the ground electrode.

An aspect of some embodiments of the invention includes a method of imaging an intra-body object, comprising: measuring electrical measurements using electrodes of a probe hovering inside a body lumen; identifying, based on said electrical measurements, a volume encompassing the electrodes used for the measurements as a volume free of any lumen wall; and inferring, from the identified volume free of any lumen wall, a wall in the vicinity of the probe, thereby imaging at least a portion of the object.

In some embodiments, the method further includes displaying the image of the at least a portion of the object together with and registered to a pre-acquired image of the body lumen or a portion thereof.

In some embodiments, the image of the at least a portion of the object is three dimensional. Optionally, the three-dimensional image has a size of between 1 cc and 150 cc.

In some embodiments, the method includes repeating the measuring, identifying, and inferring when the probe is at different locations, thereby generating respective different images of respective volumes, the respective volumes partially overlapping with each other, and collating the respective different images into a single image of a volume encompassing said respective volumes.

In some embodiments, the method includes repeating the measuring, identifying, and inferring at different times, generating a respective image for each of said different times, and displaying the respective images seriatim as to display a cine of the respective images on the pre-acquired image.

An aspect of some embodiments of the invention includes a method of imaging an intra-body object, comprising:
sensing electrical characteristics of the immediate environment of a multi-electrode probe hovering inside a body lumen; and
inferring from the sensed electrical characteristic shapes and positions of portions of the intra-body object that are distanced from the probe by less than a predetermined distance, thereby imaging at least a portion of the object.

In some embodiments, portions of the object distanced from the probe by a distance greater than the predetermined distance are not inferred. Optionally, the predetermined distance is 5 cm or less, for example, 3 cm or less.

In some embodiments, the object is selected from an anatomical feature of the body lumen and a medical implement in the body lumen.

In some embodiments, the method further includes tracking the probe as it senses the electrical characteristics;
determining, based on the tracking, the position of the probe in relation to a reference system; and
combining information inferred from the electrical characteristics measured when the probe was determined to be at different positions, to obtain a combined image.

Optionally, the reference system is external to the body lumen.

Optionally, the reference system is the lumen anatomy or a part thereof.

In some embodiments, wherein the electrical characteristics are sensed when the probe is stationary; and the inferring comprises inferring movements of the object in respect to the probe.

Optionally, the method further includes identifying the object by:
comparing the inferred movements to movements typical to different objects; and
selecting one of the different objects to be identified as the object based on the comparison.

An aspect of some embodiments of the invention includes a method of characterizing a position of a multi-electrode probe within a body lumen, comprising:
measuring electrical measurements using electrodes of the probe when the probe is in said position;
identifying, based on said measurements, a volume encompassing the electrodes used for the measurements as a volume free of any lumen wall; and
characterizing the position of the probe based on the shape of said volume.

In some embodiments, the method further includes determining a native shape of the volume as a shape the volume has when the probe is far from any wall of the lumen.

Optionally, characterizing the position comprises comparing the shape of the volume to the native shape, and characterizing the position as a central position if the volume has the native shape, and as a peripheral position—otherwise.

In some embodiments, the method includes identifying the shape as a nearly native shape if it has a native shape except for a portion of an outer surface of said volume that diverges from the native shape, and setting said portion of the outer surface as a wall indicator.

Optionally, characterizing the position comprises characterizing the position as being closer to lumen walls along directions leading from the position to a wall indicator than in other directions.

In some embodiments, characterizing the position comprises characterizing a distance between a wall and said position based on a distance between said position and a wall indicator.

In some embodiments, the electrical measurements include impedance measurements between two of the probe electrodes.

In some embodiments, the electrical measurements include impedance measurements at a probe electrode in reference to a reference electrode.

In some embodiments, the measuring comprises:
injecting a current to at least one electrode of the probe electrodes,
measuring voltage developed, in response to said injection, between two of the probe electrodes;
measuring electrical current running, in response to said injection, between said two of the probe electrodes; and
estimating an impedance value based on said measured voltage and current.

Optionally, the electrical current is injected to a single electrode of the probe, and the voltage and currents are measured between two electrodes of the probe other than said single electrode.

In some embodiments, electrical currents of common frequency and opposite phases are injected to two of the probe electrodes, and the voltage and current are measured between two other electrodes of the probe.

In some embodiments, said measuring electrical measurements comprises measuring voltage and current at 20 or more, optionally 50 or more, excitation schemes, each excitation scheme is defined by the one or more electrodes to which current is injected and by the two electrodes between which voltage and current are measured.

In some embodiments, identifying the volume comprises comparing results of the electrical measurements to results of electrical measurements made or simulated to be made with the probe in known spatial relationships to a wall.

Optionally, said known spatial relationships differ from each other by at least one of distance between the probe and the wall, and orientation of the probe in respect to the wall.

In some embodiments, the method further includes determining a first spatial relationship between the volume and the probe.

Optionally, the method further includes determining, using a first frame of reference, position and orientation of the probe;
setting a location in an image as a location of the probe; and
displaying the image with the volume displayed at the first spatial relationship to the location set in the image.

Optionally, the image is a pre-acquired image of the body lumen or a portion thereof.

Optionally, setting the location in the image is based on registration between the pre-acquired image and first frame of reference.

In some embodiments, the latter two aspects may be combined together.

An aspect of some embodiments of the invention includes a method of identifying a volume free of any lumen wall surrounding a multi-electrode probe within a body lumen, comprising:
measuring electrical measurements using electrodes of the probe;
comparing results of the electrical measurements to results of electrical measurements made or simulated to be made with the probe in known spatial relationships to a wall; and
identifying, based on said comparison, a volume encompassing the electrodes used for the measurements as a volume free of any lumen wall.

In some embodiments, said known spatial relationships differ from each other by at least one of distance between the probe and the wall, and orientation of the probe in respect to the wall.

The method may further include identifying a wall in the vicinity of the probe based on said comparison.

In some embodiments, the method further includes determining a native shape of the volume as a shape the volume has when the probe is far from any wall of the lumen.

In some embodiments, the electrical measurements include impedance measurements between two of the probe electrodes.

Optionally, the electrical measurements include impedance measurements at a probe electrode in reference to a reference electrode.

In some embodiments, the measuring comprises:
injecting a current to at least one electrode of the probe electrodes, measuring voltage developed, in response to said injection, between two of the probe electrodes;
measuring electrical current running, in response to said injection, between said two of the probe electrodes; and
estimating an impedance value based on said measured voltage and current.

Optionally, the electrical current is injected to a single electrode of the probe, and the voltage and currents are measured between two electrodes of the probe other than said single electrode.

Optionally, electrical currents of common frequency and opposite phases are injected to two of the probe electrodes, and the voltage and current are measured between two other electrodes of the probe.

In some embodiments, said measuring electrical measurements comprises measuring voltage and current at 20 or more, optionally 50 or more, excitation schemes, each excitation scheme is defined by the one or more electrodes to which current is injected and by the two electrodes between which voltage and current are measured.

An aspect of some embodiments of the invention includes an apparatus configured to carry out any one of the preceding claims.

For example, the apparatus may be an apparatus for characterizing a position of a multi-electrode probe inside a body lumen, the apparatus comprising a memory saving instructions and a processor for carrying out the instructions, and wherein instructions saved on the memory cause the processor to:
access electrical measurements made using electrodes of the probe when the probe was in said position;
identify, based on said electrical measurements, a volume encompassing the electrodes used for the measurements as a volume free of any lumen wall; and
characterize the position of the probe based on the shape of said volume.

In some embodiments, the memory further saves a native shape of the volume, said native shape being a shape the volume is expected to have when the probe is far from any wall of the lumen.

In some embodiments, the instructions cause the processor to compare the shape of the volume to the native shape, and characterize the position as a central position if the volume has the native shape, and as a peripheral position—otherwise.

Optionally, the instructions cause the processor to set as a wall indicator a portion of an outer surface of said volume that diverges from the native shape.

Optionally, the instructions cause the processor to characterize the position as being closer to lumen walls along directions leading from the position to a wall indicator than in other directions.

In some embodiments, the instructions cause the processor to characterize a distance between a wall and said position based on a distance between said position and a wall indicator.

In some embodiments, the instructions further cause the processor to:
control injection of a current to at least one electrode of the probe electrodes;
access measurements of voltage developed, in response to said injection, between two of the probe electrodes;
access measurements of electrical current running, in response to said injection, between said two of the probe electrodes; and
estimate an impedance value based on said voltage and current.

Optionally, the processor controls the electrical current to be injected to a single electrode of the probe, and the voltage and currents are measured between two electrodes of the probe other than said single electrode.

In some embodiments, the processor controls injection of electrical currents of common frequency and opposite phases to two of the probe electrodes, and accesses voltage and current measured between two other electrodes of the probe.

In some embodiments, said instructions cause the processor to access electrical measurements of voltage and current at 20 or more excitation schemes, each excitation scheme is defined by the one or more electrodes to which current is injected and by the two electrodes between which voltage and current are measured.

Optionally, said instructions cause the processor to access electrical measurements of voltage and current at 50 or more excitation schemes.

In some embodiments, the instructions cause the processor to compare results of the electrical measurements to results of electrical measurements made or simulated to be made with the probe in known spatial relationships to a wall.

In some embodiments, said known spatial relationships differ from each other by at least one of distance between the probe and the wall, and orientation of the probe in respect to the wall.

In some embodiments, the apparatus further includes an interface configured to connect between the processor and the multi-electrode probe.

According to an aspect of some embodiments of the present disclosure, there is provided a system for estimating a location of a wall of an intra-body lumen, the wall being within an examined region including a plurality of examined locations examined for wall presence, and the system including: a ground electrode; at least one probe configured to be positioned in the intra-body lumen, the at least one probe including a first electrode and at least a second electrode; a parameter measuring device, configured to generate an electrical field by transmitting a current from the first electrode to a ground electrode; a measuring device configured to measure, for each of a plurality of reference positions of the at least one probe, a respective wall distance-indicating parameter; the measurement of the wall distance-indicating parameter including a measurement of a voltage difference of the electrical field between the first electrode and the second electrode, the second electrode being positioned at a second position within the intra-body lumen; a processor and a memory storing processor instructions, wherein the processor instructions instruct the processor to calculate a respective wall-presence evidence value for each of a respective multiplicity of the plurality of examined locations, using the wall distance-indicating parameter; and wherein the processor instructions further instruct the processor to: calculate a measure of local impedance for a region around the first electrode, using: the measurement of the voltage difference between the first and second electrodes, and a measure of the current between the first electrode and the ground electrode; and convert the measure of local impedance to an estimate of proximity of the wall of the intra-body lumen to the first electrode.

According to some embodiments of the present disclosure, for each of the plurality of examined locations, the instructions instruct the processor to: cumulate respective wall-presence evidence values to obtain a respective wall-presence likelihood value, and associate the obtained respective wall-presence likelihood value to the respective examined location; and estimate a shape and location of the wall within the examined region, based on the plurality of examined locations and their respective wall-presence likelihood values.

According to some embodiments of the present disclosure, the processor derives the parameter indicative of distance between the wall and the reference position from the measured voltage difference and the measure of the current, measured while the electrode occupies the reference position to which the value of the parameter is associated.

According to some embodiments of the present disclosure, a single probe of the at least one probe includes the first electrode and the second electrode.

According to some embodiments of the present disclosure, the processor estimates the location of the wall based on examined locations associated with wall-presence likelihood values beyond a minimum likelihood.

According to some embodiments of the present disclosure, for each respective examined location, the processor cumulates likelihood values for blood presence using location-associated blood evidence values calculated using the wall distance-indicating parameter measurements; and the estimate uses the likelihood values for blood presence to help determine which of the plurality of examined locations with a cumulated wall-presence likelihood value is actually a non-wall location.

According to some embodiments of the present disclosure, the processor estimates using the likelihood values for blood presence to override wall-presence likelihood values.

According to some embodiments of the present disclosure, the processor estimates an examined location to be a wall location based on the examined location having a respective wall-presence likelihood value beyond a minimum likelihood, and a respective predetermined likelihood value for blood-presence within a predetermined likelihood.

According to some embodiments of the present disclosure, the first electrode is one of a plurality of electrodes of a probe of the at least one probe positioned within the intra-body lumen, wherein each electrode of the plurality of electrodes is also used as recited for the first electrode to separately measure values of the distance-indicating parameter at different positions of the electrodes.

According to some embodiments of the present disclosure, the processor calculation of wall-presence evidence values includes treating the measurements by each of the plurality of electrodes of the probe as a contributor to the wall-presence likelihood values for wall presence.

According to some embodiments of the present disclosure, the processor estimates the location of the wall as an estimated shape of the wall over an extended portion of 3-D space.

According to some embodiments of the present disclosure, the estimated location of the wall identifies some of the plurality of examined locations as wall locations.

According to some embodiments of the present disclosure, wall-presence evidence values calculated using measurements of the distance-indicating parameter larger than a distance threshold are not cumulated by the processor for any examined location.

According to some embodiments of the present disclosure, the processor selects the distance threshold based on an estimated distance limit within which the first electrode is sensitive to presence of the wall.

According to some embodiments of the present disclosure, the distance threshold is larger than about 8-10 mm.

According to some embodiments of the present disclosure, the processor estimates a minimum distance of the wall from each reference position, based on the measurement of the distance-indicating parameter associated with the reference position; wherein the processor obtains the wall-presence likelihood values by cumulating wall-presence evidence values only for a plurality of pairs wherein each pair includes a reference position as a first member of the pair and an examined location as a second member of the pair, the first and second members of the pair being separated by at least the estimated minimum distance.

According to some embodiments of the present disclosure, the minimum distance is between about 8 and about 10 mm.

According to some embodiments of the present disclosure, the processor cumulates wall-presence evidence values only for pairs including a reference position and an examined location separated by no more than the minimum distance plus a predetermined thickness.

According to some embodiments of the present disclosure, the predetermined thickness is within a range of 1.8-2.2 mm.

According to some embodiments of the present disclosure, the wall-presence evidence values decrease monotonically with increasing distance from the minimum distance.

According to some embodiments of the present disclosure, the wall-presence evidence remains constant with increasing distance from the minimum distance to the distance of the minimum distance plus the thickness.

According to some embodiments of the present disclosure, the wall-presence evidence value varies with distance from the respective reference position at least when the distance is larger than the minimum distance and less than the minimum distance plus the thickness.

According to some embodiments of the present disclosure, the distance-indicating value is indicative of the same distance to the wall in all directions.

According to some embodiments of the present disclosure, the distance-indicating value is indicative of distance from the reference position to the wall.

According to some embodiments of the present disclosure, the measurement associated with each position of the plurality of reference positions is measured using the first electrode in the reference position.

According to some embodiments of the present disclosure, the processor cumulates blood-presence evidence values only when the examined location is within an estimated minimum distance to the wall from the reference position, the estimated minimum distance being calculated by the processor based on the value of the distance-indicating parameter associated with the reference position.

According to some embodiments of the present disclosure, the processor cumulates blood-presence evidence for a measured value of the distance-indicating parameter with values varying as a function of distance from the reference position.

According to some embodiments of the present disclosure, the processor cumulates blood-presence evidence for a measured value of the distance-indicating parameter with the same value in all directions from the reference position associated with the value.

According to some embodiments of the present disclosure, the processor cumulates blood-presence evidence for a measured value of the distance-indicating parameter with values decreasing function of distance from the reference position.

According to an aspect of some embodiments of the present disclosure, there is provided a method of measuring of local impedance using electrodes positioned within a body lumen, the method including: generating an electrical field by transmitting a current from a first electrode to a ground electrode; measuring a voltage difference of the electrical field between the first electrode and a second electrode at a second position within the body lumen; calculating a measure of local impedance for a region around the first electrode, using: the voltage difference measured between the first and second electrodes and a measurement of the current between the first electrode and the ground electrode.

According to some embodiments of the present disclosure, the measure of local impedance is proportional to the voltage difference between the first and second electrodes.

According to some embodiments of the present disclosure, the measure of local impedance is inversely proportional to an amount of current transmitted from the first electrode.

According to some embodiments of the present disclosure, less than 10% of current flowing from the first electrode flows through the second electrode.

According to some embodiments of the present disclosure, the ground electrode is at least 5 cm away from each of the first and second electrodes.

According to some embodiments of the present disclosure, the ground electrode and the first and second electrodes are all on the same probe.

According to some embodiments of the present disclosure, the method includes performing the generating, measuring, calculating, and converting as recited for the first electrode and second electrode, with the first electrode in roles as recited for the second electrode and the second electrode in roles as recited for the first electrode, wherein the first and second electrodes transmit their respective currents at different respective frequencies.

According to some embodiments of the present disclosure, the current transmitted from the first electrode to the ground electrode is restricted from flowing through the second electrode by an impedance at least ten times larger than the impedance between the first electrode and the ground electrode.

Unless otherwise defined, all technical and/or scientific terms used herein have the same meaning as commonly understood by one of ordinary skill in the art to which the present disclosure pertains. Although methods and materials similar or equivalent to those described herein can be used in the practice or testing of embodiments of the present disclosure, exemplary methods and/or materials are described below. In case of conflict, the patent specification, including definitions, will control. In addition, the materials, methods, and examples are illustrative only and are not intended to be necessarily limiting.

As will be appreciated by one skilled in the art, aspects of the present disclosure may be embodied as a system, method or computer program product. Accordingly, aspects of the present disclosure may take the form of an entirely hardware embodiment, an entirely software embodiment (including firmware, resident software, microcode, etc.) or an embodiment combining software and hardware aspects that may all generally be referred to herein as a “circuit,” “module” or “system” (e.g., a method may be implemented using “computer circuitry”). Furthermore, some embodiments of the present disclosure may take the form of a computer program product embodied in one or more computer readable medium(s) having computer readable program code embodied thereon. Implementation of the method and/or system of some embodiments of the present disclosure can involve performing and/or completing selected tasks manually, automatically, or a combination thereof. Moreover, according to actual instrumentation and equipment of some embodiments of the method and/or system of the present disclosure, several selected tasks could be implemented by hardware, by software or by firmware and/or by a combination thereof, e.g., using an operating system.

For example, hardware for performing selected tasks according to some embodiments of the present disclosure could be implemented as a chip or a circuit. As software, selected tasks according to some embodiments of the present disclosure could be implemented as a plurality of software instructions being executed by a computer using any suitable operating system. In some embodiments of the present disclosure, one or more tasks performed in method and/or by system are performed by a data processor (also referred to herein as a “digital processor”, in reference to data processors which operate using groups of digital bits), such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well. Any of these implementations are referred to herein more generally as instances of computer circuitry.

Any combination of one or more computer readable medium(s) may be utilized for some embodiments of the present disclosure. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device. A computer readable storage medium may also contain or store information for use by such a program, for example, data structured in the way it is recorded by the computer readable storage medium so that a computer program can access it as, for example, one or more tables, lists, arrays, data trees, and/or another data structure. Herein a computer readable storage medium which records data in a form retrievable as groups of digital bits is also referred to as a digital memory. It should be understood that a computer readable storage medium, in some embodiments, is optionally also used as a computer writable storage medium, in the case of a computer readable storage medium which is not read-only in nature, and/or in a read-only state.

Herein, a data processor is said to be “configured” to perform data processing actions insofar as it is coupled to a computer readable memory to receive instructions and/or data therefrom, process them, and/or store processing results in the same or another computer readable storage memory. The processing performed (optionally on the data) is specified by the instructions. The act of processing may be referred to additionally or alternatively by one or more other terms; for example: comparing, estimating, determining, calculating, identifying, associating, storing, analyzing, selecting, and/or transforming. For example, in some embodiments, a digital processor receives instructions and data from a digital memory, processes the data according to the instructions, and/or stores processing results in the digital memory. In some embodiments, “providing” processing results comprises one or more of transmitting, storing and/or presenting processing results. Presenting optionally comprises showing on a display, indicating by sound, printing on a printout, or otherwise giving results in a form accessible to human sensory capabilities.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium and/or data used thereby may be transmitted using any appropriate medium, including but not limited to wireless, wireline, optical fiber cable, RF, etc., or any suitable combination of the foregoing.

Computer program code for carrying out operations for some embodiments of the present disclosure may be written in any combination of one or more programming languages, including an object-oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Some embodiments of the present disclosure may be described below with reference to flowchart illustrations and/or block diagrams of methods, apparatus (systems) and computer program products according to embodiments of the present disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

### BRIEF DESCRIPTION OF THE SEVERAL VIEWS OF THE DRAWINGS

Some embodiments of the present disclosure are herein described, by way of example only, with reference to the accompanying drawings. With specific reference now to the drawings in detail, it is stressed that the particulars shown are by way of example, and for purposes of illustrative discussion of embodiments of the present disclosure. In this regard, the description taken with the drawings makes apparent to those skilled in the art how embodiments of the present disclosure may be practiced.

In the drawings:

FIG. 1A schematically illustrates a flowchart of a method of estimating a wall of an intra-body lumen, according to some embodiments of the present disclosure.

FIG. 1B schematically illustrates collection and use of complementary evidence for use in estimating wall location and shape, according to some embodiments of the present disclosure;

FIG. 1C is a schematic flowchart representing an example of internal FIGS. 4A-4C, according to some embodiments of the present disclosure;

FIG. 2 schematically illustrates a system configured for use in estimating locations of a wall of an intra-body lumen and/or device therein, according to some embodiments of the present disclosure;

FIGS. 3A-3H and 3J schematically illustrate a shell-and-sphere method for accumulating wall-presence evidence (in the shell) and blood-presence evidence (within the sphere), according to some embodiments of the present disclosure;

FIGS. 4A-4C schematically represent (in cross-section) detection of a wall protrusion during movement of an electrode along pathways, with sensing at a plurality of reference position, according to some embodiments of the present disclosure;

FIG. 4D shows wall protrusion together with a cumulative profile generated by combining all the circles of FIGS. 4A-4C, according to some embodiments of the present disclosure;

FIG. 4E schematically represents a configuration of an imaged target and probe comprising a plurality of electrodes moving in direction, approximately corresponding to the measurement conditions associated with the data of FIGS. 4F-4G, according to some embodiments of the present disclosure;

FIG. 4F represents self-impedance data recorded by a plurality of electrodes passing over target, according to some embodiments of the present disclosure;

FIG. 4G represents local impedance data recorded by a plurality of electrodes passing over target, according to some embodiments of the present disclosure;

FIGS. 5A-5D schematically illustrate conversion of wall-presence evidence associated with examined locations (FIG. 5A) into an estimated shape and location of wall (FIG. 5D), according to some embodiments of the present disclosure;

FIGS. 6A-6B schematically illustrate two alternative methods of making electrical measurements in accordance with the determination of a local impedance as described in relation to FIGS. 8C-8D, according to some embodiments of the present disclosure;

FIG. 7 schematically illustrates a more detailed measurement circuit corresponding to an implementation of the measurement configuration of FIG. 6A, according to some embodiments of the present disclosure;

FIGS. 8A-8B schematically illustrate aspects of a bipolar electrode sensing configuration, according to an example of the present disclosure; and

FIGS. 8C-8D schematically illustrate aspects of a local impedance electrode sensing configuration, according to some embodiments of the present disclosure.

### DESCRIPTION OF SPECIFIC EMBODIMENTS OF THE INVENTION

The present invention, in some embodiments thereof, relates to the field of imaging within body cavities by intra-body devices (for example: multi-electrode probes); and more particularly, to imaging using electrical fields generated and sensed inside the body.

### Overview

A broad aspect of some embodiments of the present disclosure relates to methods of imaging intra-body objects, such as an anatomical feature or a device in an intra body lumen. Examples of imaged anatomical features include, for example: heart wall, fossa, ostium of a pulmonary vein, and/or heart valves. Examples of imaged devices include, for example: implants, pacemakers, anchors and/or clips.

Imaging is performed on the basis of differences in measured electrical signals, which are in turn induced by electrical characteristics of the imaged object which distinguish them from their environment. The electrical signals may include, for example, voltage sensed within electrical fields generated using electrodes inside the body and/or outside of it, and/or currents that pass through at least one electrode of a probe, influenced by imaged object and the impedance of the medium contacting the probe. In some embodiments, local impedance as described hereinbelow is calculated from the electrical signals, and used for imaging (e.g., determination of lumenal wall shape).

An aspect of some embodiments of the present disclosure relates to a method of imaging of a bounding surface (herein, referred to as a “wall”) defined by an intra-body object. The bounding surface may be a wall of a body lumen, or a surface of another object such as an implanted object within the body lumen.

The method, in some embodiments, uses a plurality of measurements made from an intra-body electrode (e.g., an electrode of a probe hovering inside a body lumen), each measurement being indicative of the electrical environment surrounding the electrode's position. More generally, this position is referred to herein as a “reference position”, as the term is defined hereinbelow. The reference position is preferably a position actually occupied by an electrode. However, e.g., in a two sensing-electrode configuration, the reference position may be in another location, for example, a position which is the geometric mean of the positions of the sensing electrodes. The electrode position at the time of measuring may be itself known from further position measurements. The position measurements may be made by any suitable method. They may be, for example, electrical measurements relying, e.g., on measurements of a plurality of crossing electrical fields imposed through the region the electrode is moving through. In some embodiments, electrode position is measured in another way, e.g., by use of stereoscopic reconstruction methods operating on a plurality of X-ray image streams taken from different angles, and/or magnetic field strength measurements.

The just-mentioned property of “being indicative” of the electrical environment surrounding the electrode's position derives, in some embodiments, from differences in the electrical properties of the medium (e.g., blood) which surrounds the electrode, compared to electrical properties of an object (e.g., a wall of cardiac muscle) being imaged. In the case of the example of blood and cardiac muscle, the wall being imaged is relatively dielectrically insulating compared to the medium. As a result, impedance measured by the electrode in this example increases as it approaches the wall: the wall is a relatively greater impediment to the flow of electrical current than the medium. The inverse may occur when the imaged wall comprises a material which is relatively conductive compared to blood, e.g., a metal. The rate of accumulation of new measurements may be, for example, from about 10 Hz to about 1000 Hz.

More particularly, in some embodiments of the present disclosure, each of the plurality of measurements is treated as indicative of a wall distance from the electrode. Herein, the value of each such measurement is referred to as the value of a “wall distance-indicating parameter”. For example, relative to a baseline impedance of the electrode immersed in a blood volume distant (e.g., more than 1 cm distant) from any interfering structure, impedance will tend to increase as the electrode approaches a higher-impedance structure such as a lumenal wall of a heart. Impedance is the wall distance-indicating parameter in this example. The wall distance-indicating parameter is optionally measured and expressed in other units, however; for example, in terms of current and/or voltage measured. In some embodiments, a baseline value of the wall-distance indicating parameter is calibrated using measurements made when the sensing electrode is near the center of a lumen, at the edges of which the target object to be imaged is located. As those measurements begin to change detectably, the object is, typically, right at the edge of the sensor's zone of sensitivity, reaching a maximum change, typically, upon nearest approach to the object being mapped.

From a single such value of a wall distance-indicating parameter, the information indicated is “how far away” the wall is (at least, this is indicated once the electrode approaches the wall to within the distance range of its own sensitivity). It may be noted that this method of calculation/evidence accumulation allows determining positions of the wall without visiting it (e.g., without coming within 1 mm of it).

This indicated information is treated, in some embodiments, as evidence that the position of the electrode is within some measurement-indicated distance of the wall. It may be noted that the direction of the wall is not directly given from the wall distance-indicating parameter. It may also be noted that a certain value of the wall distance-indicating parameter may not be associated with an actual constant distance between electrode and wall. For example, if the wall is flat, its effect on impedance as a function of distance from the electrode may be different than if the wall is curved toward or away from the electrode, even if the point of closest approach has the same distance. Or—if there are two wall portions nearby, the effect on impedance may increase to a level consistent with just one wall portion at an even closer distance. Accordingly, evidence of wall distance from a single measurement is per se tentative.

Additionally, or alternatively, the evidence of wall distance may be understood as evidence of a size of volume encompassing the electrode used for the measurements which is a volume free of any wall (e.g., any lumenal wall). When the wall is outside the sensitive range of the electrode, the wall-free volume may be set to a value appropriate to this range, e.g., a 1-cm radius volume. In this case, however, the measurement does not provide positive evidence of the distance of the wall. In some embodiments, the shape of the volume defined by the range of sensitivity of the electrode (its zone of sensitivity) is treated as spherical (estimated to be spherical). In this case, wall distance evidence is the same in every direction from the electrode.

Optionally, the estimation of the zone of sensitivity used in wall mapping defines a non-spherical volume, e.g., a volume which is wider along one axis than along other axes. The choice of the estimated shape of the zone of sensitivity (spherical or ellipsoidal, for example), is preferably dictated by the conditions of measurement set for the measuring electrode. In some embodiments of the present disclosure, these conditions are explicitly set so that actual sensitivity is approximately spherical, allowing the simplification that a given value of a distance-indicating parameter can be mapped to a single radius from the reference position.

In some embodiments, measurement conditions are set so that the zone of sensitivity to wall presence is more elongated; e.g., ellipsoidal or dumbbell shaped for two sensing electrodes, or even comprising a plurality of separate zones of sensitivity. In these cases, sensor orientation and inter-electrode distances become relevant to the reference position. Furthermore, the reference position might be defined, e.g., as the geometrical average of position in space of the electrodes being used to measure the distance-indicating parameter, rather than as a position centered on the location of one sensing electrode. In some embodiments, a probe carrying a plurality of electrodes is flexible, so that the shape and/or orientation of the actual zone of sensitivity is potentially variable as the probe is deformed and/or re-oriented by contacting objects in its environment. Because of these complications, it may be preferable that the wall distance-indicating parameter be measured so that the sensitivity zone can be well-approximated by a sphere. The sensitivity zone may have a radius, for example, of about 8-10 mm around the associate reference position (e.g., around the measurement electrode).

In some embodiments, the distinction between evidence of a wall at some indicated distance within sensing range, and absence of wall evidence within sensing range is made by tracking two kinds of evidence: “wall-presence evidence” (when a wall influence on the measurement is observed), and “blood-presence evidence”, which is accumulated based on the sensing range, if there is no sensed wall; or based on the indicated wall distance, if there is a sensed wall.

In some embodiments of the present disclosure, it is convenient to accumulate wall-presence evidence by associating it to locations (herein, referred to as “examined locations”) defined jointly by the reference position's location in space, and the distance to the wall from that reference position indicated by the measurement of the wall distance-indicating parameter. Similarly, blood-presence evidence is accumulated by associating it to examined locations defined jointly by the reference position's location in space, and the distance from the reference position within which the value of the wall distance-indicating parameter suggests there is no wall. In some embodiments, the examined locations are defined as a three-dimensional array of voxels (voxels being data elements representing volumes of space arranged in a packed array of such volumes of space).

In some embodiments, wall-presence evidence is accumulated for examined locations within a shell centered on the reference position. Accumulation of evidence, in some embodiments, comprises addition (optionally weighted addition) of a numerical indication of per-measurement evidence to a number associated with each examined location. Accumulation need not be linear (e.g., there can be a maximum value of evidence accumulated, an asymptotic value to which accumulation of evidence approaches, or another form of accumulation). Additionally, or alternative, accumulation may comprise collection, e.g., of data tokens which collectively indicate of “how much” evidence has been accumulated.

The shell is a spherical shell, for example, if the zone of sensitivity is isotropic, although it can be another shape. The shell is set to a suitable thickness of e.g., about 2 mm (1.8-2.2 mm). Optionally, the shell thickness is larger or smaller; for example, 1 mm, 3 mm, or another thickness. For embodiments in which the examined locations are defined as a three-dimensional array of voxels, the shell thickness may be selected to ensure a continuous thickness around the shell of at least 1, 2, 3 or more voxels. Optionally, every modeled examined location within and/or intersecting with the shell is given the same increase in value for a same measurement. Optionally, evidence is accumulated as a function that changes for different portions of the shell, e.g., added evidence values may decrease or increase in magnitude with increasing distance from the reference position. Optionally, accumulated evidence is weighted based on what proportion of the volume of an examined location (e.g., a voxel) intersects with the shell.

Blood-presence evidence is accumulated for examined locations which lie within the wall-presence evidence shell. Accumulated values of blood-presence evidence can be the same for all locations that receive an evidence increase, e.g., in all directions and/or at all affected distances. Optionally the accumulation of blood-presence evidence is graded, e.g., decreasing with increasing distance from the reference position.

There is no particular requirement that the volume of examined locations which accumulate blood evidence from a measurement be entirely within the shell that accumulates wall-presence evidence (although it is preferably smaller), nor is there a particular requirement that the two types of evidences be assigned as true probabilities (e.g., they need not “add up to one” as if they were alternative states of a statistical probability function).

In some embodiments, evidence values are accumulated continuously for examined locations within a larger examined region comprising them, as new measurements of the value of the wall distance-indicating parameter become accessible. This may happen, for example, in real time as measurements are made during a procedure. In some embodiments, this eventually produces two evidence maps within a common spatial frame of reference comprising the examined locations-a map of accumulated wall-presence evidence (likelihood values for wall presence), and a map of accumulated blood-presence evidence (likelihood values for blood presence).

From the accumulated likelihoods (at least of wall-presence evidence, and optionally also of blood-presence evidence), an estimation is made as to what locations in space the wall or other imaged object occupies. This allows producing an image of at least a portion of the object. The image is optionally a three-dimensional image. The image is optionally displayed together with and registered to a pre-acquired image of the body lumen or a portion thereof that the wall is a part of.

The process of this estimation, in some embodiments, comprises examining the wall-presence map to determine what wall shape is supported by the evidence available. The wall shape may be selected, for example, as the total boundary of the region, at which wall-presence evidence accumulates to above some threshold. However, this criterion alone may lead to erroneous wall presence estimations. For example, gaps in the regions visited may produce the illusory appearance of internal “inclusions”. While inclusions may be disregarded (and only outer boundaries considered as possible walls), this method still does not suffice to distinguish actual wall boundaries from a boundary with an unvisited region. It is preferable to distinguish these cases, for example, as it may provide a physician with a more dependable sense of the intralumenal working environment of a probe if they can easily distinguish the boundary of exploration (which may shift considerably), and the boundary of the lumen itself (which should remain permanent, once established).

One way to create this distinction is to include consideration of the blood-presence evidence. At boundaries with regions which are simply unexplored, the blood-presence evidence should extend at least up to, and usually beyond the region of accumulated wall-presence evidence. At true wall locations, the region of accumulated wall-presence evidence will extend beyond the region for accumulated blood-presence evidence.

Another way to track the difference between the two boundary types is to accumulate, in parallel with the accumulation of wall-presence evidence, associated values of the wall distance-indicating parameter. When the wall distance-indicating parameter is normalized for the amount of accumulated wall presence-evidence, it should be lower for examined regions which truly contain a wall, since these will sometimes be approached more nearly, and sometimes less nearly. Increased variance of the value of the wall distance-indicating parameter provides another optional indication distinguishing actual wall locations from locations which are merely near the boundary of the explored region.

The repetition rate of image generation may be, for example, from 100 Hz to 0.1 Hz. In some embodiments, different images generated based on measurements made when the probe was at different places are collated into a single image that covers a larger volume than each of the collated images cover alone. In some embodiments, the images being collated overlap, wholly or partially, so the obtained collage is continuous. In some embodiments, images taken within one heartbeat are collated together. In some embodiments, images taken at several heartbeats at the same phase of the heart cycle (e.g., as may be defined by body surface ECG) may be collated together. In some embodiments, collated together are images generated from data collected by the probe from nearby places (e.g., images based on data collected when the probe moved within a volume of 1 cc or less). This may allow showing the time development of a single place, generating a kind of cine. Optionally, such a cine may be analyzed to identify the imaged place. For example, if the data was collected when the probe was stationary within a heart chamber, and the imaged object is shown in the cine to move at a frequency that is double that of the heart, it may be concluded that the image is of a leaflet of a heart valve.

In some embodiments, the imaging method is used in collaboration with tracking information, indicative to the location, and optionally also the orientation, of the probe at the moment of sensing the electrical characteristics. The location and/or orientation may be characterized in relation to, for example: an external frame of reference, the lumen's anatomy or a part thereof, and/or another intra body device. In some embodiments, information collected by the probe from different locations and/or different orientations may be used together to provide information on a larger imaged scene (e.g., of a larger field of view), than that imaged by the probe at a single position.

Thus, in some embodiments, if the position and orientation of the probe at each point that was characterized is known from a tracking system, the present methods allow building a shape of the wall (or other object) by merging together indications providing evidence of wall presence.

In some embodiments, the present method allows for analyzing movement of an anatomical feature, for example, a heart wall, a heart valve or leaflet, etc. This may be accomplished with a stationary probe, and receiving information indicative to how the surroundings of the stationary probe change over time. Such measurements may be analyzed to obtain information on movement around the probe, and such movements may be compared to known movements of different objects (e.g., heart wall portions, leaflets, etc.), to facilitate identification of the anatomy moving near the stationary probe.

The imaging method presented herein may be based on a method of probe position characterization. The characterization may include a determination whether or not the probe is within a threshold distance from an anatomical feature or other object of distinguished electrical characteristics, such as a wall, fossa, leaflet, different medical devices, or the like. Alternatively, or additionally, the characterization may include determining the distance to the object and/or the direction leading from the probe to the object or to the sensed part thereof. Such probe position characterization may be accomplished by making electrical measurements using electrodes of the probe, identifying (based on results of these measurements) a “no wall region” around the probe, and characterizing the position of the probe based on the shape of this no wall region. In some embodiments, the shape of the no-wall region may be compared to shapes of no wall regions known to exist with a wall at a certain distance and/or orientation to the probe, and the current probe position is characterized by comparing the measured no-wall region to those expected to be obtained under different conditions, thus identifying the conditions under which the current measurements are taken, and characterizing the probe position accordingly.

For example, in some embodiments, measurements expected to be obtained by a probe with no wall in its surrounding may be compared to measurements obtained in practice. If the two are indicative of no-wall region of the same shape, the probe position may be characterized as “central”, i.e., has no wall in a predetermined radius. The predetermined radius may be, for example of 1, 3, or 5 cm, depending on the range for which the measurement system is sensitive. If the measured shape is different from the expected central shape, the wall position may be characterized as “peripheral”.

The shape of the measured no-wall region and its deviations from the shape of the expected no-wall region can also be indicative to details on distance between wall and probe, which electrode is closest to the wall, etc.

In some embodiments, a portion of the outer surface of the “no wall region” is identified as a “wall indicator” if it deviates from the expected shape, and characterize the position of the probe as being closer to a wall along a direction leading to this wall indicator than along any other direction. Optionally, the distance to the wall along this direction is identified as the distance from the probe to the wall indicator.

Herein, reference is made to “walls” (e.g., the wall of an intra-body lumen). A wall may be of a body lumen or of a device, as long as they have electrical characteristics distinguishable from those of the medium between the probe and the walls around it. In case the body lumen is a heart chamber, this medium is blood. In some embodiments, the method may include hovering a multi-electrode probe inside a body lumen (e.g., a catheter probe comprising 4, 10, 20, or other plurality of electrodes), and sensing electrical characteristics of the immediate environment of the probe. This environment may extend, in some embodiments, to a distance of 1 to 5 cm from the probe, depending on the sensitivity of the probe and the prominence and decay distance of the sensed electrical characteristics.

An aspect of some embodiments of the present disclosure relates to systems and/or methods for making electrical measurements indicative of wall position. In some embodiments, said systems and/or methods potentially enhance the accuracy of analysis results relying on simplifying assumptions about the sensitivity range of the electrical measurements being analyzed. In some embodiments, the simplifying assumptions include an analysis procedure that proceeds as if the sensitivity range is spherically shaped around the sensor.

In some embodiments of the present disclosure, a measure designated “local impedance” is defined which has the potential advantage of well-approximating a spherical function of sensitivity to changes in impedance as an electrode moves within its environment. Local impedance is distinct in particular from “bipolar impedance”. Similar to the sensitivity function of bipolar electrode measurement (impedance measured between two nearby electrodes), the sensitivity function of local impedance is actually “lobed”. However, the method of measuring local impedance results in one of the electrodes used in the measurement considerably dominating in sensitivity—e.g., one lobe has a larger sensitivity range than the other. Considering that lobe alone, the result is, in some embodiments, a sensitivity function which is, for practical purposes of mapping, the same in most directions from the dominant electrode, apart from a distortion region in directions toward the less-sensitive, non-dominant electrode.

In a typical example, the measurement of local impedance uses three electrodes-a transmitting electrode (also referred to herein as the dominant electrode), a passive sensing electrode, and a ground electrode. Most current passing out of the transmitting electrode reaches the ground electrode. Current may be measured by any suitable ammeter device and/or method, for example as known in the art of electrical measurements.

The passive sensing electrode passes relatively little of that current (e.g., less than 10%, 5%, 1%, or 0.1%), but does sense (at its location) a voltage associated with the electrical field accompanying the flow of current. That sensed voltage can be treated, in some embodiments, as helping to characterize the impedance characteristics of the electrical environment of the transmitting electrode.

In a local impedance measurement (contrasting with bipolar electrode measurements), current flows mainly from one of the probe electrodes (the dominant/transmitting electrode) to ground. The ground is optionally located relatively far from the probe, e.g., it may be a body surface electrode.

It may be noted that this condition of probe electrode-to-ground electrode current flow is somewhat as may be found in a monopolar electrode configuration. However, in pure monopolar electrode operation, an amalgam of the whole of the electrical environment between ground and the transmitting electrode is “sensed” as a single bulk impedance, also referred to herein as “self-impedance”. As a result, electrical characteristics (e.g., electrical impedance) specific to the environment immediately surrounding the transmitting electrode are swamped out in the measurement by contributions from other areas. The result is considerably less localized sensing of environmental impedance than for the bipolar electrode measurement scenario just described.

Local impedance may provide measurement sensitivity that isolates impedance characteristics in the immediate environment of the transmitting electrode. A local impedance measurement scheme relies on a second probe electrode, referred to herein as the passive sensing electrode. This electrode is configured to measure voltage established at its own position by an electrical field generated as current flows between the transmitting electrode and the ground. Itself, the passive sensing electrode passes none or relatively little of that current. The measurement of voltage at the second electrode can be used to mathematically cancel out impedance contributions from environmental regions further away from the transmitting electrode. The cancellation is not perfect, since it is still “contaminated” somewhat by impedances in the environment concentrated immediately around the second electrode.

More mathematically-oriented descriptions of how “local impedance” may be characterized are provided in the detailed descriptions hereinbelow.

In some embodiments, the effect of a “local impedance” measurement scheme may be considered as shrinking one of the two lobes of a bipolar impedance. This produces a sensitivity function that the inventors have realized is potentially well suited to approximation as a sphere, at least for purposes of impedance-based wall mapping analysis.

Analysis of impedance measurements “as if” they arise from a spherical sensitivity function has potential advantages for wall mapping, insofar as it provides a relatively simple analysis framework allowing direct conversion of impedance changes measured as an electrode moves toward a target into a distance (radius) to that target.

For example, once a spherical sensitivity function can be assumed, the distance between the transmitting electrode and a sensed structure may be inferred from a change in local impedance induced by the structure (compared to that impedance in absence of the structure), disregarding the orientation of a sensing apparatus comprising the electrode, and the direction of the structure relative to the sensing apparatus.

It should be understood that actual sensitivity function is not required to be ideally spherical in order to provide reliable results if analyzed using the simplifying assumption that this function is spherical.

To the extent that the sensitivity function treatment as spherical is justified, there are potential advantages in reduced computational complexity, particularly in real-time mapping applications where an operator prefers to have a live-updating view of probe position with respect to visited anatomy.

These potential advantages may be counterbalanced, however, if the actual sensitivity function is sufficiently non-spherical to introduce unacceptable error, and/or if special calibration or other procedures are needed in order for the “spherical assumption” to be used practically to produce maps of a desired accuracy and/or resolution. For example, when the sensitivity function (even if treated as a sphere), actually has a more complex shape than spherical (for example, a bi-lobed shape as in a bipolar electrode's sensitivity function), then there may be a loss in mapping resolution unless some of the simplicity of a sphere is abandoned. Additionally, or alternatively, the procedure of mapping may be complicated somewhat to gather auxiliary information that is not needed for analyzing local impedance measurements. For example, orientation information regarding an electrode pair used for bipolar measurements may be required for analyzing bipolar impedance measurements. Such orientation information may be determined by performing in situ calibrations and/or probe orientation tracking.

It may be noted that, depending on the geometry of the probe, a probe being moved around in an intralumenal space may naturally have a “leading side” (generally more distal) and a “trailing side” (more proximal). The passive sensing electrode, in some embodiments, is placed preferably where it is most often on the trailing side, where the distorting effects of its own minor local lobe of sensitivity may have a lowered practical effect on mapping measurements.

It should also be noted that a probe may carry more than a single pair of electrodes. This can be used in different ways to tune the effective sensitivity function.

In one example of a variation which is optionally implemented using a multi-electrode probe: increasing the distance between the transmitting electrode and the passive sensing electrode (e.g., by using a pair of electrodes with a greater separation between them) will also tend, in some embodiments, to increase the sensitivity range of the local impedance measurement. There is also a tendency to a tradeoff in loss of resolution, however. This may be acceptable at larger distances; e.g., for mapping on initial approach to a wall structure. In some embodiments, mapping switches to using local impedance measurements from closer-together pairs of electrodes when the probe gets closer to targets of mapping such as lumenal walls. For a multi-electrode probe, electrode distance is optionally referred to in terms of “skip value”. For example, a skip value of 1 refers to the use of adjacent electrodes for calculation of a local impedance measurement. Measurement with a skip value of 2, 3, or another value refers to the use of electrodes separated by “skip value minus one” intervening electrodes.

In another example of a variation which is optionally implemented using a multi-electrode probe: for a single transmitting electrode, more than one other electrode may be available even at the same distance as a passive sensing electrode. For example, there may be an available passive sensing electrode at an equal distance on either side of a transmitting electrode. Either of these electrodes will “distort” the sensitivity function of the local impedance measurement slightly differently due to impedance influences near to them. In some embodiments, these two slightly different local impedance measurements are used together (e.g., by averaging), or alternately (e.g, by discarding one of them based on characteristics indicative of greater distorting influences).

In a third example of a variation which is optionally implemented using a multi-electrode probe: more than one transmitting electrode may be used for a given passive sensing electrode. For example, on probe comprising a circular arrangement of electrodes, there may be a transmitting electrode on either side of a diameter of the circular arrangement, with a passive sensing electrode in between. The transmitting electrodes may transmit at different frequencies. In some embodiments, as the probe moves, signal changes which are correlated in both magnitude and timing are optionally attributed to impedance influences (e.g., wall structures) approaching particularly near to the passive sensing electrode. Such signal changes are optionally disregarded, at least for mapping purposes, reducing the effective “distortion” contribution of the passive sensing electrode.

In a fourth example of a variation which is optionally implemented using a multi-electrode probe, and optionally a two-electrode probe: there is no particular limitation on an electrode being used only as a transmitting electrode or passive sensing electrode. Electrical current is optionally driven through a plurality of electrodes driven at different respective frequencies, and sensing arranged so that passive sensing electrode(s) for a given frequency are not themselves configured to pass current at that frequency-even if they are being actively driven to pass current at another frequency. This type of implementation may be achieved, for example, using frequency analysis methods and/or resonance/frequency-filtering circuits, as known in the art.

It should also be noted that there is no particular restriction on the transmitting electrode and passive sensing electrode being located on the same probe. Two probes may be operated side-by-side, for example. In another example, a multielectrode probe may be deployed within a lumenal space (e.g., deployed to a roughly spherical arrangement of electrodes), and left statically in place while another electrode-carrying probe is maneuvered to map the lumenal wall. Optionally, the static electrodes are used as passive sensing electrodes, and one or more electrodes on the maneuvered probe are used as the transmitting electrode. Unless probe movements are coordinated, measurements using separate-probe embodiments will tend to vary both as a function of changing wall proximity to the transmitting electrode and as a function of inter-electrode distance (since this affects sensitivity range, as already discussed). To adjust for this, electrode positions can be separately tracked, and for each measurement received, a sensitivity function used which is appropriate to the relative distance of the electrode known from this electrode position tracking. A potential advantage of this type of mapping embodiment is that it can reduce or remove changes in measurement values due to changes in the impedance environment of the passive sensing electrode. However, calibration may be required to correctly adjust for static wall proximity in the case of some of the statically positioned passive sensing electrodes. This may be done, for example, by initially treating these electrodes themselves as transmitting electrodes, determining their own wall proximity upon reaching their statically deployed positions, and afterward using these determinations to adjust measurements of local impedance that uses them as passive sensing electrodes.

### Definitions and General Conditions of Operation

In some embodiments of the present disclosure, electrical transmission conditions use alternating current, typically at radio frequencies within a range of about 10-100 KHz. Currents are typically kept to 100 μA or less (e.g., according to requirements of ISO60601), and voltages within the range needed to support that current (e.g., about 30 mV for impedances of approximately 300Ω). In this regime, “constant current” refers to constant current cycle amplitude.

Electrodes may be referred to herein as operating as a “transmitting electrode” or as a “sensing electrode” (sometimes specified alternatively as a “passive sensing electrode”), to emphasize that the electrode passes a minimal amount of current compared to the transmitting electrode. In some embodiments, an electrode operates simultaneously and/or alternately in both of these roles. For example, an electrode operating as a transmitting electrode at a first frequency optionally is also configured to operate as a sensing electrode at a one or more other frequencies (e.g., the electrode may sense voltages alternating at other frequencies, without passing current, or passing only a small fraction of the total current being transmitted by the other electrodes). Through an electrode operating in sensing mode at a certain frequency, there may flow, for example, no more than 10%, 1%, or 0.1% of the total current being transmitted at that frequency.

Examples herein may be described in terms of constant current transmission or constant voltage transmission. Constant current transmission in particular has potential advantages for safety, circuit construction, and/or simplification of calculations. It should be understood, however, that embodiments of the present disclosure are not limited to only the specific paradigm discussed. Impedance may be in general calculated (e.g., for particular frequency) when both voltage and current are known, whether or not one of them is held constant.

In some useful configurations, the transmitting and sensing electrodes may be considered as being relatively close to one another compared to their sensitivity range; for example, mounted on a same probe within 4 mm of each other while the range of sensitivity is 2× or larger than that.

Before explaining at least one embodiment of the present disclosure in detail, it is to be understood that the present disclosure is not necessarily limited in its application to the details of construction and the arrangement of the components and/or methods set forth in the following description and/or illustrated in the drawings. Features described in the current disclosure, including features of the invention, are capable of other embodiments or of being practiced or carried out in various ways.

### Method of Estimating Location of a Wall

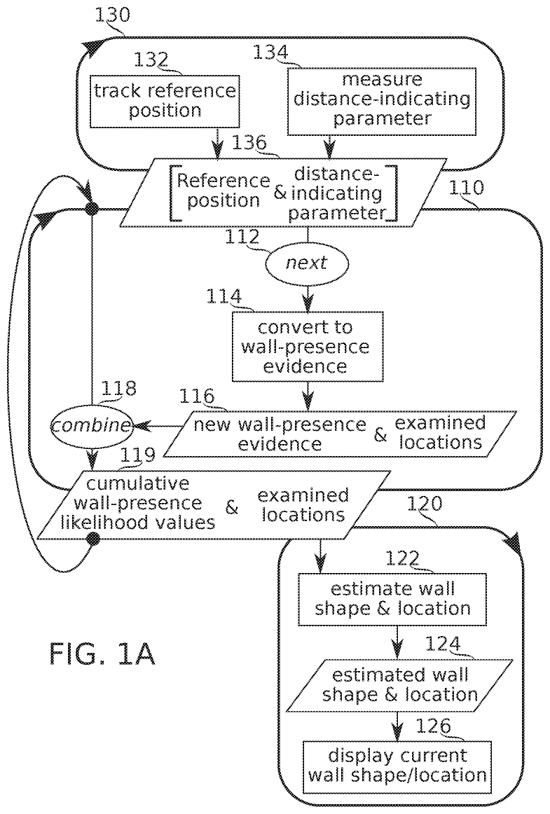

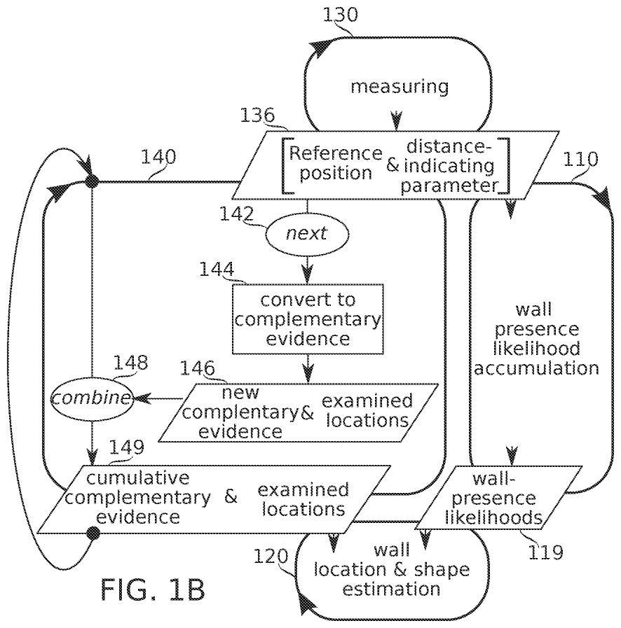

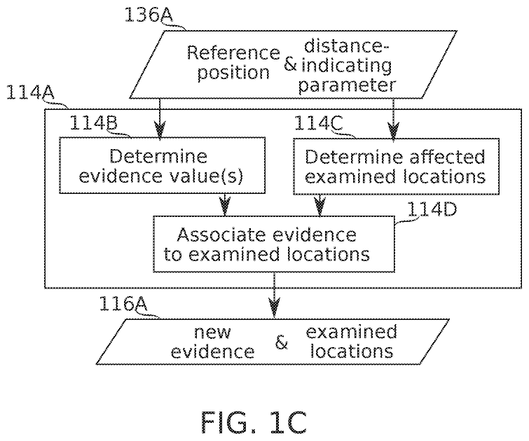

Reference is now made to FIG. 1A, which schematically illustrates a flowchart of a method of estimating a wall of an intra-body lumen, according to some embodiments of the present disclosure.

Blocks bordered with a looped arrow represent recurring groups of operations of some embodiments of the method. Block 130, for example, represents recurring measurement operations, block 110 represents recurring operations of wall presence likelihood accumulation, and block 120 represents recurring estimation of wall location and shape. Loops of operations in different looped arrow blocks may occur asynchronously from one another; that is, a given loop block does not necessarily need to wait for completion of a cycle of any other loop block before restarting its own cycle. Optionally, however, cycles may be implemented wholly or partially synchronously, e.g., because they share computational or other resources, and/or under the control of a synchronizing controller.

Blocks 110 and 130 interface through a data structure 136 comprising a stream, array, formula, list, and/or other data structure which associates measurements of a distance indicating parameter with corresponding reference positions (herein, flowchart blocks shown as non-right angled parallelograms represent data which may be used and/or produced by operations described in relation to rectangular blocks). Each such set of associated measurements is referred to herein as an “entry”, whether the association is direct (e.g., adjacent locations in a computer memory), or more indirect (e.g., association via timestamp and/or other linking information).

Blocks 110 and 120 interface through a data structure 119 comprising an array, list, or other data structure, which associates cumulative wall-presence likelihood values with examined locations. A convenient implementation of data structure 119 is as a 3-D array, with indexes of the array being proportional to spatial coordinates of the examined location, and values of the array being cumulative wall-presence likelihood values. Data structure 119 may have more dimensions, however, e.g., to allow representation of time, such as phasic time of a heartbeat and/or phasic time of respiration. Additionally, or alternatively, the cumulative wall-presence values may be represented along with other values which support the operations of block 120.

Within loop block 130, in some embodiments, at block 134 a distance-indicating parameter is measured, along with a block 132 by tracking (e.g., measuring) of a corresponding reference position.

The distance-indicating parameter may comprise any measurement which yields a value that generally changes as the distance between the object whose shape and location are being estimated and the reference position increases or decreases. This typically comprises measurement of voltage, current, and/or impedance, as sensed by one or more electrodes positioned on a probe moving near the targeted object (such as an intralumenal wall of a heart chamber). In some embodiments, another sensor is used. For example, the time of first echo return of an omnidirectional sonic “chirp” may be used as the distance-indicating parameter.

The value actually used for the distance-indicating parameter can be one or more of the measurement values directly (e.g., voltage, current, and/or impedance), and/or any version of them which has been suitably processed, for example by one or more operations such as normalization, averaging and rescaling.

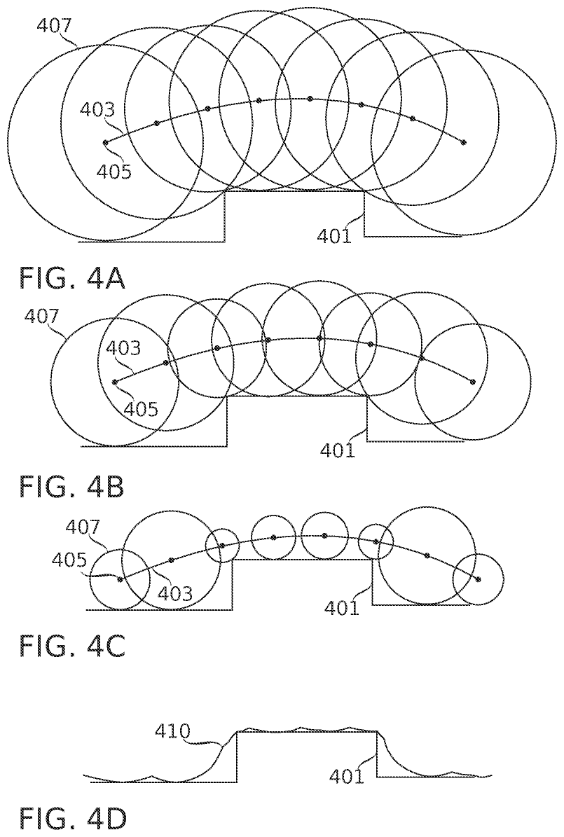

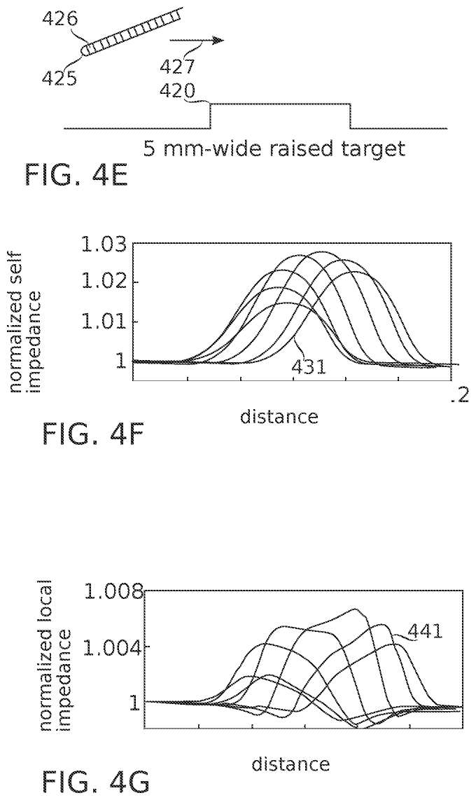

Examples of paradigms for measurement details are described, for example, in relation to FIGS. 4E-4G, herein.

The reference position is optionally measured by any suitable method capable of tracking the position of the measurement electrode (or other measurement sensor) used to perform measurements which generate a value for the distance-indicating parameter. The reference position may be occupied by the measurement sensor itself, or it may be a position calculated to lie elsewhere; for example, the geometric average of the position of two electrodes used jointly as a sensor.

It is convenient, in some embodiments of the present disclosure, for the tracking sensors used to track the reference position to be electrodes carried on the same probe as the sensor(s) for the distance-indicating parameter. These electrodes are optionally the same as the electrodes used to measure the distance-indicating parameter. For example, there may be a plurality of electrical fields generated at different frequencies, crossing each other within a sensing region comprising the reference positions. Measurements of these fields may be used to determine the reference positions. In a simple case, each field provides a measure which is treated as indicative of position along a different spatial axis, but this does not exclude other methods of converting electrical field measurements to position such as are known in the art. Apart from electrical field measurements used to measure reference positions, other electrical fields may be generated (e.g, at further different frequencies) according to the paradigm selected for making measurements of the distance-indicating parameter.

In FIG. 1A, all associations of reference positions and distance-indicating parameters are collected under block 136. The data of block 136 need not be maintained and/or collected in one structure at one time, however. For example, these data may be communicated serially to the processor implementing block 110.

The measurement of block 130 is itself not necessarily performed as an integral part of the method of intra-body lumen estimation; for example, all measurements may be performed during a first period, and the operations of blocks 110 and 120 performed during a later, second, period by accessing the values of data structure 136. Preferably, however, the operations of blocks 110 and 120 are performed concurrently with operations of block 130, allowing implementation of real-time updating of wall shape and location estimated from newly generated entries in data structure 136, as they arrive.

The description of the operations of each loop of loop block 110 begins at block 112, with the selection of one or more (next) entries of block 136. For clarity, processing of one entry at a time will be described. Accessing entries in temporal order of their original generation is preferable (e.g., for producing live updates of wall shape and location), but not required.

At block 114, in some embodiments, the entry selected at block 112 is converted to wall-presence evidence. Evidence is generated based on the value of the distance-indicating parameter. Assignment of the evidence to positions in spatial coordinates (the examined locations) is based on the spatial coordinates of the reference position. Briefly: each location in a “shell” of examined locations is given some nominal increase in the likelihood that it is the location of a portion of the wall (or other object) being estimated. At some values of the distance-indicating parameter (e.g., larger than a threshold of the value and/or its indicated distance), there may be no wall-evidence accumulated at all. In some embodiments, the cutoff is selected to be a value beyond which wall distance cannot be reliably determined it (e.g., when it is near enough to a baseline value that noise in its measured value cannot be distinguished from signal indicating wall presence). However, reliability need not be the reason for the cutoff, e.g., the cutoff may be placed at a distance value selected to increase sensing resolution. Additionally, or alternatively, the amount of wall-evidence added may be reduced as the distance increases, e.g, reflecting distribution of the wall presence evidence over a larger surface area, and/or decreased and/or more uncertain sensitivity at greater distances.

Other evidence (such as blood-presence evidence) may be accumulated, for example, as described in relation to the additional operations described in FIG. 1B. Further details of this are described, for example, in relation to Figures IC and/or 3A-3H and 3J.

The operations of block 114, in some embodiments, yield the output data of data block 116, comprising new wall-presence evidence, and the examined locations it is associated with.

At block 118, in some embodiments, this is combined with data structure 119, which maintains an overall cumulative record of what wall-presence evidence has been calculated for the set of examined locations.

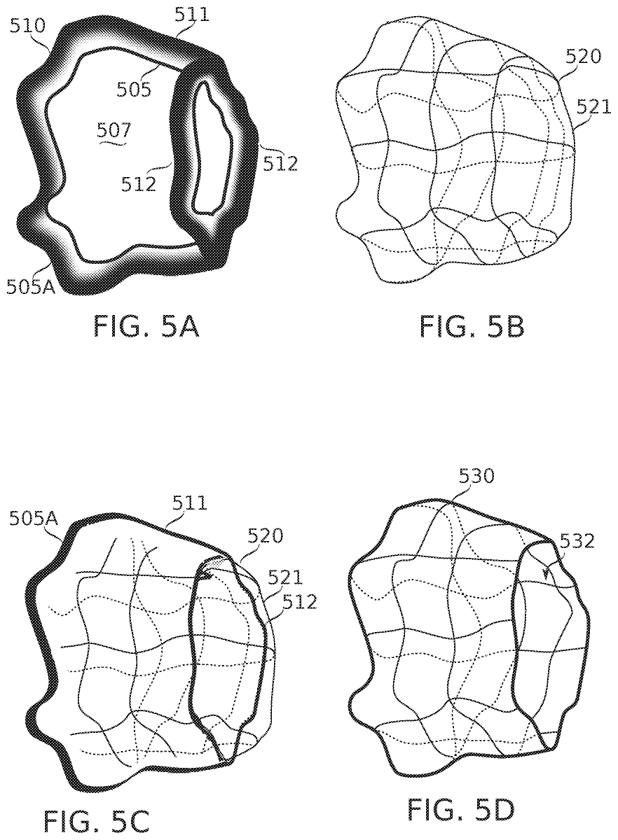

At block 120, in some embodiments, wall shape and location are estimated and optionally displayed. Estimation of wall shape and location is performed at block 122. This comprises examination of the spatial distribution of wall evidence among examined locations to determine which of those examined locations actually comprise a wall—that is, a boundary separating the medium in which the sensor moves from another material making up the target object such as surrounding tissue and/or material of an implanted device such as metallic and/or polymeric material. Briefly, the outer bounds of the region having wall evidence are determined and processed to select where the wall boundary itself should be drawn. There are some issues associated with this, determination such as how to exclude boundaries of the region of wall-presence evidence which are merely due to the limits of measurement exploration, and how to exclude “inner” boundaries of the zone of wall-evidence, which may adjoin still more interior regions which were explored, but for which no wall evidence was accumulated. FIG. 1B explains a method of tracking additional information which may assist in this determination. FIGS. 4A-5D illustrate this and other aspects of the estimation of block 122.

Data block 124 represents the wall shape and location that was estimated at block 122. Optionally, at block 126, the currently estimated wall shape and location (represented by data block 124) is processed to produce an image to display, and displayed. The operations of block 120 can be repeated as the state of evidence changes. The rate of reprocessing may optionally be fast enough to produce a live-updating view (e.g updating at 10-100 Hz). This provides a potential advantage for guidance of the measuring probe, since the locations it moves into can be “colored in” with wall position estimates quickly enough to be perceptually concurrent with the movement itself.

It should be noted that wall-presence evidence may be calculated and cumulated according to algorithms differing in some particulars from what was just described in relation to FIG. 1A. For example, the accumulation of evidence may just comprise cumulatively collecting the data of block 136, with the wall estimation being performed repeatedly on this data upon accessing each new wall shape and location estimation. However, recalculating all evidence at each estimation cycle would be relatively inefficient, and amount to subsuming the operations of blocks 110 (and optionally block 140) into block 120.

Wall-presence evidence recorded may also take other forms than the “volume-associated” evidence operation mentioned above and also discussed in relation to Figures IC and/or 3A-3J.

For example, in some embodiments, wall-presence evidence is derived from examination of the amount of change of distance indicated by the distance-indicating parameter, proportional to amount of movement toward or away from the edges of the currently available cloud of reference positions and associated distance-indicating parameters.

In directions pointed toward actual wall boundaries (and within the distance range of wall-sensitivity), extrapolating the rate of change outward allows determining locations where zero-distance would be measured, corresponding to an estimated position of the wall. In contrast: in directions where the measurement cloud boundary is simply a “not yet explored” area, extrapolation may not reach such a zero-distance point (e.g., the slope in distance may be flat or even increasing); or the zero-distance may be reached only at a distance beyond a defined sensitivity range of the measurement, so that it can be identified as spurious. Compared to the use of shell-distributed evidence, this slope-based method of accumulating evidence relies on having at least two spaced-apart measurements within the zone of sensitivity, sufficient to define a gradient of the distance-indicating parameter.

To reduce the computational load of this procedure, a rapid estimate of the slope may be calculated for the position of each new measurement of the distance-indicating parameter, optionally only in directions within the range of wall-sensitivity to some edge of the currently available cloud of reference positions. The converse calculations (accounting for how the new measurement affects slopes at previously measured positions) may be postponed or omitted, so that it's not necessary to perform full slope recalculations upon integration of each new measurement.

It should be noted that in practice the slope-calculation procedure also amounts to calculating wall-presence evidence (e.g., the slope metric is subject to noise tending to “blur” the edge, so no single measurement is determinative—each one is evidential), and cumulating wall evidence associated to examined locations (e.g., in the form of the likelihood of being a wall boundary established by the neighborhood of zero-distance “hits” defined by association with the position of a given examined location).

### Collection of Complementary Evidence of Wall Location

Reference is now made to FIG. 1B, which schematically illustrates collection and usage of complementary evidence for use in estimating wall location and shape, according to some embodiments of the present disclosure.

In some embodiments, conversion of the “cloud” of wall-presence likelihood values accumulated according to the method of FIG. 1A into a wall shape and location estimate makes use of complementary data. Calculation and tracking of this data are illustrated within block 140 of FIG. 1B, which otherwise may be understood as duplicating FIG. 1A, including, e.g., blocks 110, 120, 130, and 136 corresponding to the descriptions of these blocks in relation to FIG. 1A.

The operations and data of blocks 142, 144, 146, 148, and 149 relate to one another substantially as described for blocks 112, 114, 116, 118, and 119 of FIG. 1A. At block 142, an entry is selected from the data of block 136. At block 144, this is converted into “complementary evidence” used in estimating wall shape and location. At block 148, this evidence is combined into the data of block 149 with whatever evidence of the same time was previously collected.

The complementary data generated may differ between embodiments. Selected examples are next described; it should be understood that these are not limiting. A general feature of the complementary evidence is that it distinguishes among different examined locations with substantial wall-presence evidence according to whether that evidence is indicative of an actual wall boundary, or rather indicative of a limit of exploration, or a limit of wall-presence sensitivity.

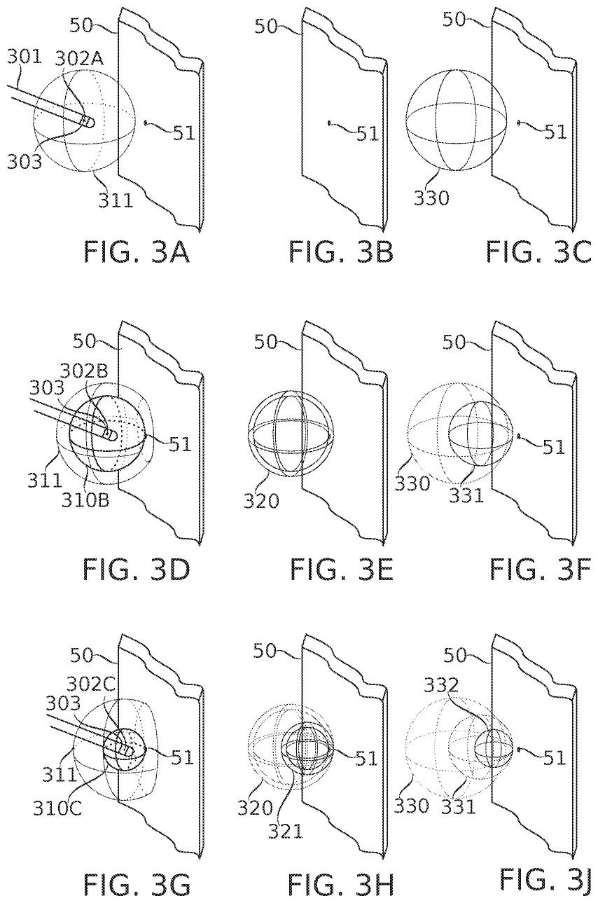

In some embodiments of the present disclosure, the complementary evidence collected in block 140 is “blood-presence” evidence. This may be calculated, for example, as a volume within a spherical (or otherwise-shaped) region surrounding the reference position, reaching to a radius according to the radius of the shell of wall-evidence accumulated within block 110. This sphere may be entirely within the wall-evidence shell, or it may somewhat overlap. Preferably, the “blood-presence” sphere of examined locations does not include at least some of the positions included within the corresponding “wall-presence” shell, but this is not required in all embodiments. Collection and use of blood-presence evidence as complementary evidence used in estimating wall location and shape is detailed, for example, in relation to FIGS. 3A-3H and 3J and 5A-5D. In overview, consideration of one or both of two criteria is preferably made as part of wall shape and location estimation. First, there should be a low level and/or a very sharp drop in blood-presence evidence near and/or across a true wall boundary. This distinguishes between the wall-presence evidence boundary at true wall boundaries, vs. boundaries marked by coming into the wall-sensitive range of the distance-indicating parameter. Second (and optionally), the low level and/or sharp drop in blood-presence evidence preferably happens along with a corresponding rise in wall-presence evidence occurring near the border, somewhat before it reaches a rapid fall-off at the outer edge. This rise may occur because wall presence evidence is added to a decreasing range from the true boundary as it is approached, leading to relative enrichment of wall-presence evidence within a band extending just short of the wall boundary itself. Using this criterion may increase sensitivity to excluding a “lip” boundary of wall-presence evidence that may form near actual wall boundaries, but is actually only an artifact of the limits of exploration. While features described for the wall-presence evidence such as the boundary ramp-up may alone be indicative of the distinction between true wall boundaries and artefactual boundaries in the wall-presence evidence zone, comparison to corresponding blood-presence evidence potentially helps clarify such differences.

Another type of complementary evidence which may be accumulated, in some embodiments of the present disclosure, is the distance (e.g., the value of the distance-indicating parameter) associated with each further piece of wall-presence evidence. For boundary locations where the variance of evidence-associated distance is relatively high and increasing toward the boundary, it is indicative that the same wall piece was seen at both closer and further distances. This structure in variance is likely to invert at artefactual boundaries of the zone wall-presence evidence.

Alternatively, to using variance, average distance associated with accumulated evidence can be tracked. This average may tend to decrease moving toward actual wall boundaries, but increase moving toward artefactual boundaries where there is no actual wall to force a decrease of indicated distance.

In some embodiments, a slope-based type of evidence accumulation, such as is described in relation to FIG. 1A, is used as complementary evidence to assist in distinguishing actual wall-induced boundaries from well-evidence boundaries of other types.

Reference is now made to FIG. 1C, which is a schematic flowchart representing an example of internal structure of operations for converting reference position and distance-indicating parameter 136A to new evidence of wall presence for examined location 116A, according to some embodiments of the present disclosure.

Block 136A may represent, for example, block 136 of one or both of FIG. 1A or 1B. Block 114A, the conversion block, may represent, for example, one or both of block 114 of FIG. 1A and block 144 of FIG. 1B. Block 146A may represent, for example, one or both of block 116 of FIG. 1A and block 46 of FIG. 1B.

Block 114B represents the determination of evidence values using the distance-indicating parameter. In some embodiments, the evidence values calculated are volume-associated evidence, for example as described in relation to FIGS. 3A-3H and 3J and 5A-5D. Examples of volumes include shells (e.g., spherically or otherwise-shaped shells with a thickness of wall-evidence, as described in relation to FIGS. 3E and 3H), and solid interiors (e.g., a solid interior of sphere or other shape, for example as described in relation to FIGS. 3C, 3F, and 3J). A potential advantage of calculating evidence this way is that it can be parametrically quite simple—e.g., a radius, a shell thickness and function describing evidence value. The shell thickness and/or evidence value function are optionally defined as constants, further simplifying calculation. A solid sphere of blood-presence evidence may be specified similarly, without the shell thickness.

The radius, in either case, may be determined from the distance-indicating parameter in various ways. Without limitation to the following specific derivation and its details, distances to a wall can be calculated from measurements of voltage and current, for example in the following way, which uses principles of charge analysis known to skilled practitioners in the art.

From a point current source, voltage V as a function of radius r is proportional to current I, and inversely proportional to the conductivity of the blood medium σ_{blood} and the radius itself (that is,

$$\\ V ( r ) = \frac{I}{4 π {σ}_{bl ∞ d} r}$$

). This puts current, voltage, and distance all in proportionality relationships with each other. The effect of a flat wall on such a situation can be modelled using the method of image charges, by placing an image charge just as far beyond the wall as the wall is from the active electrode acting as the current source (total distance 2d, where d is the distance to the wall itself). The current (for purposes of analysis) that this image charge puts out is, however, different than the original charge due to differences in dielectric properties of the blood and the wall. The difference can be expressed by a proportionality constant μ, readily calculated from these well-known properties.

In a local impedance measurement, the measurement electrode (paired to the active electrode actually delivering current) is at a distance s from the real current source, while the image charge is at distance 2d, where d, again, is the distance to the wall itself. Assuming these distances to be at right angles to each other, the measurement electrode is thus at a distance \sqrt{4d²+s²} from the image charge. The active electrode supplies a current I, while the image charge supplies an apparent current u. Accordingly, with no wall present, the measurement electrode will sense a voltage

$$\\ {V}_{homog} ∝ \frac{1}{s} ,$$

while with a wall, it will sense a voltage of V_{wall} ∝

$$\\ \frac{1}{s} \frac{μ}{\sqrt{4 {d}^{{}_{} 2} + {s}^{{}_{} 2}}} .$$

With the other variables of these proportionalities known from measurement, a reasonable approximation to the actual distance d may be calculated.

At block 114C, examined locations, for which wall presence evidence is to be associated at block 114D, are determined (these are the “affected examined locations”, wherein what is affected is the portion of the accumulated evidence data structure representing these examined locations). The determination may comprise, in some embodiments, determining where, in the spatial frame of reference being used to track the examined locations, the reference position should be placed. The affected examined locations are then defined relative to this location, e.g., as a spherical shell have a certain inner radius and thickness, to provide the new evidence and examined locations of block 116A.

Evidence values are optionally calculated from the distance in other ways. For example, evidence that an examined location is or is not a wall location may be determined by examining a spatial rate of change in the distribution of different distance-indicating parameter values. As described in relation to FIG. 1A, this value will tend to decrease toward zero, approximately linearly with increasing proximity of the associated reference positions to a wall. When a new reference position and distance indicating parameter is used together with already accessed data, the nearby distance-indicating parameter gradient field can be calculated (or re-calculated) and examined to extrapolate where values of the distance-indicating parameter gradient are likely to reach zero. The gradient may be calculated, e.g., through the reference position. Then extrapolating the gradient to a position having the value of impedance associated with zero distance to the wall gives the position of the wall itself.

### System for Estimating Location of a Wall

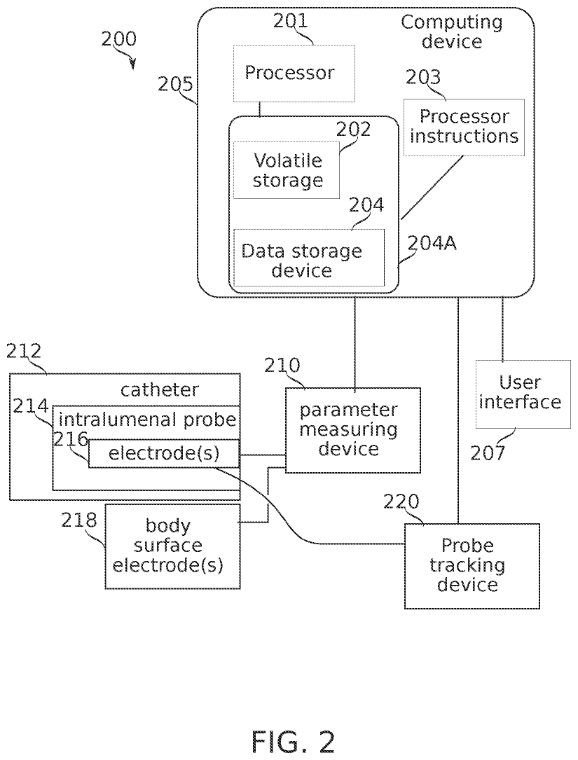

Reference is now made to FIG. 2, which schematically illustrates a system 200 configured for use in estimating locations of a wall of an intra-body lumen and/or device therein, according to some embodiments of the present disclosure.

Main subsystems of system 200 comprise computing device 205, parameter measuring device 210, and probe tracking device 220.

In the example of the system shown, parameter measuring device 210 and probe tracking device 220 are each coupled to a shared electrical probe apparatus comprising one or more body surface electrodes 218 (including one or more ground electrodes), and electrode catheter 212, which itself comprises an intralumenal probe 214 (e.g., an intracardiac probe), and one or more electrodes 216. However, it should be understood that parameter measuring device 210 and probe tracking device 220 optionally operate through independent sensing apparatuses. Moreover, there is no particular limitation that probe tracking device 220 use electrodes as position tracking sensors; it may, for example use magnetic sensing, ultrasonic sensing, irradiative energy-based sensing (e.g., X-ray sensing, radioactive sensing), or another tracking modality.

Computing device 205, in some embodiments, comprises processor 201 (which comprises, collectively, the processing capabilities of the computing device, and does not imply limitation to a single processor). Memory 204A comprises one or both of volatile storage 202 and data storage device 204 (again, these blocks comprise, collectively, available memory capabilities of the computing device). Processor instructions 203 (stored in memory 204A) instruct the processor to perform computational aspects of the system's function, for example, computational aspects of one or more of the methods described herein.

User interface 207 is configured to support receiving user-specified instructions to the system, and to provide displays and indications of device function, for example, images of wall shape and/or location.

### Boundary Estimation

Reference is now made to FIGS. 3A-3H and 3J, which schematically illustrate a shell-and-sphere method for accumulating wall-presence evidence (in the shell) and blood-presence evidence (within the sphere), according to some embodiments of the present disclosure.

FIGS. 3A, 3D, and 3G describe a probe 301 having an electrode 303 near a wall 50. The position of electrode 303 is marked as reference positions 302A, 302B, 302C, and the point in wall 50 closest to point 302 is marked 51. The distance between position 302A and point 51 is longest in FIG. 3A, the shortest between position 302C and point 51 in FIG. 3G, and intermediate between position 302B and point 51 in FIG. 3D. Accordingly, FIGS. 3A, 3D, and 3G may be understood as illustrating a time series of snapshots of probe 301 approaching wall 50. The figures also show a sphere 311, having its center at reference position 302A, 302B, 302C, and a radius that is equal to the longest distance between electrode 303 and wall 50 at which the electrode is sensitive to the existence of the wall. FIGS. 3D and 3G also show spheres 310B, 310C, respectively; each centered at a corresponding reference position 302B, 302C and having a radius representing the distance indicated by the distance-indicating parameter, i.e., the distance between points 302B, 302C and 51. In FIG. 3A there is no corresponding sphere because at the distance between points 302A and 51 in that figure, the value of the distance-indicating parameter is considered not indicative, as the distance is larger than the maximal distance at which electrode 303 is considered sensitive to the presence of wall 50.

FIG. 3E shows a spherical shell 320, within which wall-existence evidence is accumulated in the situation depicted in FIG. 3B. The spherical shell is centered upon position 302B in FIG. 3D, and has an inner radius equal to the radius of sphere 310A of FIG. 3D. Similarly, FIG. 3H shows a spherical shell 321, within which wall-existence evidence is accumulated in the situation depicted in FIG. 3G. The spherical shell is centered where position 302C is in FIG. 3G, and has an inner radius equal to the radius of sphere 310B of FIG. 3G. In addition, FIG. 3G shows spherical shell 320 to ease its comparison with spherical shell 321. As no existence of a wall is evidenced in the situation depicted in FIG. 3A, FIG. 3B shows no spherical shell. The thickness of all the depicted shells is the same. In some embodiments, this thickness is between 1 mm and 3 mm; for example, 2 mm. The range may be set, for example, based on a targeted spatial resolution of the end result, so that the sphere can be extended through an optionally quantized matrix without creating gaps thinner than the quantization interval of the matrix itself (e.g., with quantization to an interval of 1 mm, a 2 mm shell thickness may be selected). Within the thickness of each shell, wall-presence evidence can be accumulated as a constant value throughout the shell, or as another function, for example one which increases monotonically with increasing radius, decreases monotonically with increasing radius, or is highest at the center of the shell thickness.

FIGS. 3C, 3F and 3J show spheres 330, 331 and 332, respectively, inside which blood-existence evidence is optionally accumulated. All the spheres are centered at the respective positions 302A, 302B, 302C. Sphere 331 has the same radius as sphere 311, since absence of a wall in the range of sensitivity is evidence that the whole sphere within the range of sensitivity is blood-filled. Spheres 332 and 330 have radii equal to the inner shell of spherical shells 320 and 321, respectively, since the distance from electrode 303 to the wall may be considered evidence of the existence of blood at shorter distances. It may be noted that the two shells tend to coincide in their portions which are nearest to wall 50, and tend to separate on the side further from the wall. Away from a wall, this feature is less likely to develop. This may lead to gradients which are useful for distinguishing true wall boundaries from wall-evidence boundaries which are artefactual.

### Detection of Surface Detail

Reference is now made to FIGS. 4A-4C, which schematically represent (in 2-D cross-section) detection of a wall protrusion 401 during movement of an electrode along pathways 403, with sensing at a plurality of reference position 405, according to some embodiments of the present disclosure. Alternatively, path 403 may be understood as the centerline of a multielectrode probe, with each of points 405 being occupied by a sensing electrode.

Each of the circles 407 are drawn to a radius determined by a value of a distance-indicative parameter measured by an electrode at each corresponding reference position 405. In 3-d space, they could be considered as spherical, or another shape if the sensitivity of the sensing electrodes was non-spherical. Pathways 403 are shown at successively closer locations to wall protrusion 401 in FIGS. 4A, 4B, 4C. Circles 407 become correspondingly smaller with decreasing distance. This also serves to increase the resolution; e.g., smaller circles can fit more tightly into the lower corners of protrusion 401 before encountering an upper corner or adjacent flat area. Nevertheless, it may be seen that even when the circles are relatively large compared to the protrusion, the cumulative profile traced out by their circumferences gives a clear indication of the presence of a feature. Of particular note is that the pathways 403 need not themselves be specially shaped to probe into crevices of the adjacent surface; simply passing over them along a smooth path is sufficient to reveal their presence and general shape.

Brief reference is also made to FIG. 4D, which shows wall protrusion 401 together with a cumulative profile generated by combining all the circles of FIGS. 4A-4C. While this profile is not squared-up (that is, high spatial frequencies are distorted), the overall dimensions of protrusion 401 are correctly reproduced. In the case of biological surfaces 410, square protrusions would be an extreme case. Insofar as wall features are more usually curved, loss of sharp detail would have a lowered impact on imaging fidelity.

Reference is now made to FIG. 4E, which schematically represents a configuration of an imaged target 420 and imaging probe 425 comprising a plurality of electrodes 426 moving in direction 427, approximately corresponding to the measurement conditions associated with the data of FIGS. 4F-4G. Further reference is made to FIG. 4F, which represents self-impedance data recorded by a plurality of electrodes 426 passing over target 420, as may be used in further processing to determine target position and/or shape, according to some embodiments of the present disclosure. Additional reference is made to FIG. 4G, which represents local impedance data recorded by a plurality of electrodes 426 passing over target 420.

Each of FIGS. 4F-4G illustrates seven superimposed recordings, each associated with a different one of different electrodes 426 of probe 425 as is drawn over a 5 mm-wide raised target 420. Each trace shows a clear deviation in (normalized) measured impedance magnitude as one of the electrodes 426 nears, passes over, and then distances from target 420.

In the case of FIG. 4F, self-impedance magnitude is shown as 431, defined as total impedance from the measurement electrode to ground as the measurement electrode generates current which flows to a distant ground electrode. The impedance is calculated using the (time-varying) current and a simultaneously measured voltage from the same electrode. The self-impedance includes influences from both nearby and far-away structures, which tends to swamp out high spatial frequency information (reducing sharp edges and resolution).

In the case of FIG. 4G, local impedance is shown. Local impedance is measured differentially by using the voltage as also measured for FIG. 4F, and subtracting from it a voltage measured by another electrode, as it is observed to fluctuate at the frequency of generation used by the first electrode. The other electrode is operated in a high impedance mode so that leakage current through it is minimized. Local impedance is thus somewhat of a mix of the impedance environments of both electrodes, with the primary current-delivering electrode's environment dominating. Operated this measurement configuration, the recordings retain more of the high frequency (high resolution) information, as evidenced by the faster rises and falls in impedance amplitude 441 as each electrode passes over the edge of target 20. The undershoots seen in several of the traces are artifacts of the subtractive method used to generate the local impedance measurement. Some traces are larger in amplitude than others. Apart from some differences in calibration, the largest amplitude traces are from electrodes held closer to the target, where the deviation in impedance created was correspondingly larger.

Comparing FIG. 4F with 4G, it may also be seen that the relative amplitude of the change in impedance was smaller in the local impedance mode, which corresponds to cancellation of a shared component of their self-impedances (that is, the part of the current pathway to ground which each measurement electrode shared). In general, as the two electrodes used to calculate a local impedance come further apart in space, they gain a larger distance of sensitivity (less is canceled out), while losing resolution. In a multi-electrode array, different combinations of electrodes are optionally used to make imaging measurements, potentially improving overall joint performance in range and resolution.

Various signal injection options may be utilized. For example, a stimulation may be injected to one electrode, two electrodes, or a larger number of electrodes. Signals injected simultaneously may be of the same frequency. In some embodiments, signals injected at different frequencies are considered as different injections, and may occur simultaneously or serially. Preferably, measurements are made by electrodes that are not used for signal injection at the same frequency and at the same time, since signals read by injecting electrodes may be noisier than those read by electrodes that do not inject during the measurement at the measurement's frequency. However, in some embodiments, measurements are made on electrodes used for the signal injection.

A combination of electrodes used for signal injection and electrodes (or electrode pairs) used for electrical characteristics measurements is referred to herein as an excitation scheme. In some embodiments, the number of excitation schemes used to characterize a single position is more than 50. In some embodiments, a smaller number of excitation schemes (e.g., 10, 20, 30, 40, or intermediate or larger number) is used. In some embodiments, more than 50 excitation schemes are used; for example, 55, 100, 200, or any intermediate or larger number. In some embodiments, the number of excitation schemes available depends on the number of the probe electrodes. For example, in embodiments wherein a single electrode is used for signal injection and a pair of electrodes is used for reading, the number of available excitation schemes is

$$\\ N \frac{N - 1}{2} ,$$

where N is the number of electrodes, including the probe electrodes and a ground, non-probe electrode. In the case of a probe carrying 10 electrodes, this supports 55 excitation schemes. In some embodiments, the ground electrode may be one of the catheter electrodes.

In some embodiments, the size of the environment sensed by the probe may depend on the excitation scheme. For example, if all the signals are injected only to the probe electrodes, and read only by the probe electrodes, the sensed environment may be smaller than if body surface electrodes take place in the signal injections and/or reading. Being insensitive to parts of the body that are far from the probe provides a potential advantage in that the results may be insensitive to far sources of noise or to processes that take place far away from the probe (e.g., breathing). Being sensitive for a larger range provides a potential advantage in that larger volumes may be imaged. Accordingly, the excitation schemes may be selected according to the goal of the imaging process. The volume that can be imaged in the various excitation scheme may vary between about 1 cm³ and 150 cm³, although it is contemplated that imaging larger or smaller volumes may also be achieved.

### Rejection of Spurious Boundaries

Reference is now made to FIGS. 5A-5D, which schematically illustrate conversion of wall-presence evidence associated with examined locations (FIG. 5A) into an estimated shape and location of wall (FIG. 5D), according to some embodiments of the present disclosure. In some embodiments, the shape and location of the wall are estimated over an extended portion of 3-D space.

The outlined (and partially shaded) regions in FIG. 5A represent portions of a “lining” of accumulated wall-presence evidence 510 for a portion of a body lumen interior. Wall presence evidence 510 may be an accumulation of evidence generated, for example, as described in relation to FIGS. 3E and 3H-a plurality of wall-distance indicating parameter measurements made at many different reference locations within a lumen. Darker shading represents more gathered wall-presence evidence.

To allow seeing some details, shading due to wall-presence evidence has been suppressed everywhere except in transverse cross-section 511, and around ring 512 (which is viewed obliquely). Although there “really is” lumenal wall limiting transverse section 511 to create outer boundary 505A, there is no lumenal wall limiting the boundary of ring 512 on the right-hand side. In other words, the wall evidence which contributes to darkening ring 512 really only “belongs” to the outer boundary 505A which also happens to coincide with the inner lumenal wall. The boundary at the right-hand side of ring 512, on the other hand, is merely an artifact of the as-yet incomplete exploration of the lumenal space. So, there are some places near ring 512 which correctly give evidence of a wall, but leave open some ambiguity as to where that wall is positioned. The problem to be solved, then, is how to determine on which side of regions near ring 512 the apparent boundary is actual (e.g, along boundary 505A), and on which side the apparent boundary should be treated as an artifact of incomplete sampling.

Regions in transverse section 511 with a greater accumulation of wall-presence evidence 510 (near the edges of the region) are colored darker, up to the edge of boundary 505A. The gradient of shading shown is a result of wall presence evidence being generated within a smaller and smaller volume as a probe approaches the wall itself. This may allow regions near the wall to “get more evidence” than regions further from the wall.

The reason that transverse section 511 is incomplete on the right-hand side (exposing ring 512) is just because there are regions of the lumen on that side not visited for measurement. The right-hand portion of the lumenal wall is beyond ring 512: too far beyond the visited regions to have been detected.

Away from ring 512, it is reasonably clear where the actual wall exists. Border 505 represents an interior boundary of the lining-shaped region which has accumulated wall-presence evidence. Interior to border 505 is region 507, which, even though it was visited for measurements, has accumulated no wall-presence evidence. It is too far from any wall for reliable analysis of distance-indicating parameter values. It is fairly clear just from the direction of the wall evidence gradient in most locations that boundary 505A is the correct position of the lumenal wall.

However, in some portions of the lumen, e.g., particularly near ring 512, it is potentially ambiguous whether the edge of the area with wall-presence evidence is indicative of an actual wall, or simply an absence of sufficient exploration. One way to resolve such ambiguities is through the use of “blood presence” evidence, as now discussed in relation to FIG. 5B-5D.

FIG. 5B shows a 3-D mesh view of the extents (region 520) of accumulated blood-presence likelihood values, complementary to the wall-presence likelihood values of FIG. 5A. The transverse section 511 of FIG. 5A corresponds generally to the widest extent of region 520 seen from the same point of view as FIG. 5B. Around much of its perimeter, region 520 is slightly inset in its shape compared to wall-presence region 510. However, at the right side, it extends further, to include a zone 521 which was visited for measurement, but in which no wall presence was detected.

In FIG. 5C, region 520, as well as transverse section 511, and ring 512 from FIG. 5A are superimposed (but transverse section 511 and ring 512 are suppressed where region 520 overlaps them). The pattern of their overlap confirms that border 505 is relatively deep within the wall-free zone of region 520. This is another property which may be examined to determine if a given border is a wall boundary (that is, to identify that the examined location is a wall location), or simply artefactual to the original process of wall-presence evidence accumulation. Border 505A is outside of region 520.

However, ring 512 of wall-presence evidence is now readily identified as spurious, since it is also inside wall-free (blood-presence) region 520.

In some embodiments, blood-presence likelihood values in an examined location are used to override wall-presence likelihood values—that is, used to help exclude the condition that the examined location comprises a wall location. In some embodiments, a criterion whereby blood-presence likelihood values in an examined location are used to override wall-presence likelihood values is based on the respective wall-presence likelihood value being beyond a minimum likelihood, and the respective predetermined likelihood value for blood presence being within a predetermined likelihood.

Finally, in FIG. 5D, a remaining wall surface 530 is shown, after spurious candidate wall boundaries have been discarded, e.g., as described for FIG. 5C. The viewer is immediately informed as to which boundaries are actually sensed, and which boundaries merely delimit the extent of the lumenal region which has been explored by measurement of the distance-indicating parameter. It may be noted that if ring 512 had also extended along an actual wall, wall 530 of FIG. 5D would have an inward extending “shelf” near open aperture 532.

In some embodiments, wall imaging results (e.g., including a wall model such as the wall of FIG. 5D) are presented to a doctor during a catheterization procedure, for example, during a minimally invasive structural heart disease intervention. In some such embodiments, the imaging results are displayed as an active volume, updated in real time, on a pre-acquired stills image. The pre-acquired image may provide the doctor with the anatomical context of the region that was imaged. As in some embodiments the imaged region may be small, the image may indicate to the doctor, for example, that the probe is approaching a wall, but the doctor can't tell which wall it is. Displaying the active, real-time volume on the pre-acquired image, when the image and active volume are registered to one another may help the doctor in understanding the anatomical concept of the image generated by methods described herein before. As in other places in this disclosure, a wall is mentioned as an example of an intra-body object, but the disclosure is not limited to walls and may cover other objects like other anatomical features or, in some embodiments, even medical devices or portions thereof.

In some embodiments, the volume of no wall, or at least the wall-indicating portions thereof are registered to and displayed on a pre-acquired image of the body lumen. This may be obtained by determining two spatial relationships: one, between the probe and the region of no wall around it; and the other, between the probe and the pre-acquired image. The former may be determined based on the electrical measurements, and the latter may be determined using inputs from a tracking system that tracks the location of the probe in the body lumen. An exemplary system that may be used for such tracking is described in International Patent Application Publication No. WO2019/034944, the contents of which are included herein by reference, in their entirety. Having these two spatial relationships established, the region of no-wall may be marked on the pre-acquired image in realistic relationship to anatomical features of the body lumen that appear in the pre-acquired image.

In some embodiments, the determination of the position and orientation of the probe, as well as the determination of the volume of no wall around it may be updated in time, so the image may be periodically updated, e.g., once in 5 seconds, 1 second, 50 ms, or at any other rate. This may result in the display of moving wall indicators on the pre-acquired image, moving on the pre-acquired image with the movements of the probe. In some embodiments, the probe is stationary, and the movement of the wall indicators on the pre-acquired image may correspond to movements of wall portions of the lumen. If the wall portions are of a heart, these movements may be indicative of wall contraction and expansion during a heartbeat.

### Local Impedance and Sphericity of an Impedance Sensitivity Function

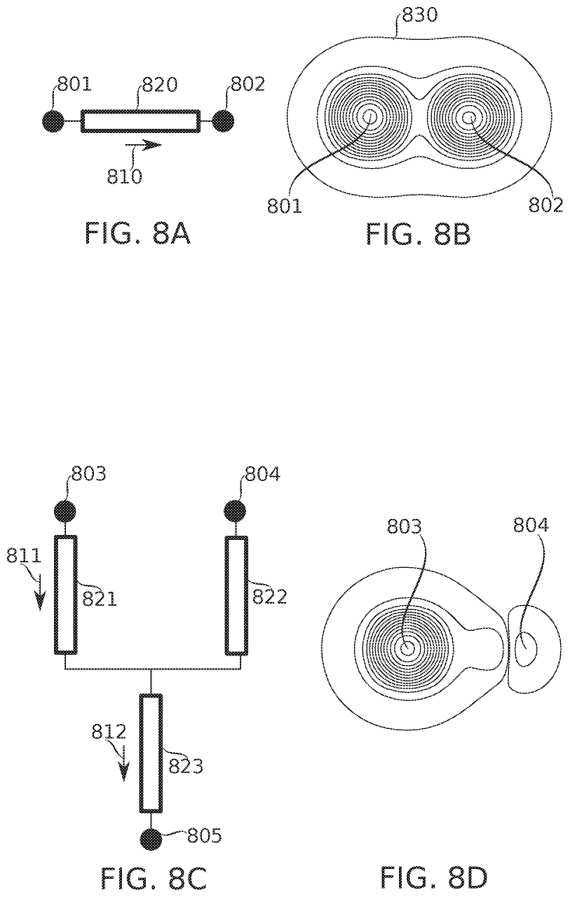

Reference is now made to FIGS. 8A-8B, which schematically illustrate aspects of a bipolar electrode sensing configuration, according to an example of the present disclosure. Reference is also made to FIGS. 8C-8D, which schematically illustrate aspects of a local impedance electrode sensing configuration, according to some embodiments of the present disclosure.

Bipolar Vs. Local Impedance Sensitivity Functions

In the present disclosure, a property referred to herein as “local impedance” is defined, and in some embodiments of the present disclosure, measurements are performed according to the definition. Measuring local impedance potentially enhances sphericity of the measurement's sensitivity function compared to other measurement methods, for example, the sensitivity function of a bipolar impedance measurement.

For reference, FIG. 8A shows a bipolar electrode sensing configuration, with a current represented by arrow 810 flowing between electrodes 801, 802, through an impedance (the bipolar impedance) schematically represented by block 820. The current itself may be alternating (bidirectional); arrow 810 indicates a case when electrode 801 is being driven actively, and electrode 802 is acting as a ground.

FIG. 8B shows a 2-D slice including the positions of electrodes 801, 802 through a typical bipolar sensitivity function. Isolines 830 represent, for example, successively greater changes in voltage needed to maintain a constant current as a high-impedance test structure (e.g., a tissue wall) is moved closer to the electrode pair. The bipolar sensitivity function of FIG. 8B is symmetrical and bi-lobed. In three-dimensional space, it may be considered as similar to the result of rotating the shown 2-D figure around an axis extending between the positions of electrodes 801 and 802. It may be understood that approximating this bi-lobed sensitivity function as a sphere, while not necessarily unreasonable, may result in very significant distortions. For example, wall positions approaching from along the axis of rotation will be sensed at a different distance, compared to wall positions approaching from along an axis orthogonal to this axis of rotation. The distortion becomes particularly strong at close distances and large impedance changes, since, for example, in these conditions it is uncertain which electrode is being approached.

In contrast, FIG. 8D shows a sensitivity function for the local impedance measurement configuration of FIG. 8C. Again, the sensitivity function is established around two electrodes 803, 804 (and may be considered to be radially symmetrical around an axis extending between these two electrodes). In this case, however, the high-impedance test structure has a much greater effect on the measured impedance (local impedance, as will next be explained) as it approaches electrode 803 as opposed to electrode 804. The difference reaches the extent that the large impedance-change isolines extend only in a rough sphere around electrode 803, and cannot be crossed by proximity to electrode 804 only. It may be seen, furthermore, that applying a threshold that allows disregarding the outermost two isolines, renders the sensitivity function practically indistinguishable from spherical. In some embodiments, the transmitting electrode is at least 5 times more sensitive to the presence of a wall at a distance of 5 mm than the passive sensing electrode is.

### Derivation of a Definition of Local Impedance

For purposes of introducing the definition of local impedance used, in some embodiments of the present disclosure, the impedance between the transmitting electrode 803 and ground 805 may be divided into a series impedance, comprising:
some local component A (impedance 821), which is due to the impedances of material concentrated in the region of the transmitting electrode, and is to be determined (and which corresponds to the “local impedance”); and
some common component C (impedance 823) which comprises the remaining impedance between the transmitting electrode and the ground.

Applying Ohm's law, this yields the equation:

$$\\ {V}_{1} = {I}_{1} ( A + C )$$

For purposes of converting local component A to a measurable quantity, the division of impedance between components A and C is determined by the position of a passive sensing electrode 804. The sum of the impedances A and C is also referred to herein as the “self-impedance” of the transmitting electrode 803.

The passive sensing electrode 804 is “passive”, in the sense that relatively little current flows through it (at least, relatively little at the transmission frequency established by the transmitting electrode 803). It may be an electrode carried on the same probe as the transmitting electrode, or on a different probe. Maintaining the transmitting and sensing electrodes 803, 804 on the same probe has the potential advantage of maintaining a more constant sensitivity function. Optionally, less than 10% of the transmission electrode's current 811 flows through the passive sensing electrode (e.g, a factor of ten less current), less than 5%, and/or less than 1%. Optionally, current 812 through impedance 823 is treated, for purposes of derivation and/or analysis as if it is effectively the same as current 811. Because of this, although it can detect the electrical field, the sensing electrode has a negligible effect on potentials in the electrical field in return.

To establish a division between local impedance A (block 821) and common impedance C (block 823), the voltage the passive sensing electrode 804 senses may be thought of as defined to be the same as the transmitting electrode would sense, if placed where the transmitting electrode was separated from the ground electrode by only the common impedance C—while still transmitting the same amount of current I₁ (current 811). In effect, this assumption treats the impedance of block 822 as if was zero (negligible). This approximation remains reasonable so long as the sensing electrode itself is restricted from passing significant current (which would distort its own local electrical field enough to invalidate the usefulness of the approximation).

This definition yields:

$$\\ {V}_{2} = {I}_{1} C$$

Then, subtracting from the previous equation and solving for the local impedance A gives:

$$\\ A = \frac{{V}_{1} - {V}_{2}}{{I}_{1}}$$

Since V₁ and V₂ are each measured relative to the same ground reference, (V₁-V₂) may equivalently be written and understood as V₁₋₂; that is, the direct voltage difference between the transmitting electrode 803 and the passive sensing electrode 804. The difference may optionally be measured directly between the two electrodes, or indirectly, e.g, with reference to a common ground, which may be ground 805. To also emphasize the condition that I₁ refers to current to a separate ground electrode g, the above definition of local impedance may thus be written equivalently as:

$$\\ A = \frac{{V}_{1 - 2}}{{I}_{1 - g}}$$

The immediate above equation should continue to be understood in the context of the current between the first and second electrodes being negligible ((I₁₋₂)≅0), in distinction to a bipolar measurement wherein current flow occurs primarily between them.

### Local Impedance Sensitivity

The above definition of local impedance gives a slightly different effective meaning to the “local” area being measured by a local impedance measurement, depending on exactly where electrode 804 is relative to electrode 803. However, the difference's main effect is in the region of low sensitivity (outer isolines). The inner isolines, being about spherically centered on electrode 803, may be considered as practically unaffected by such relative orientation changes.

This roughly spherical sensitivity function (e.g., in comparison to the bipolar electrode sensitivity function) is a potential advantage of using this definition of local impedance for performing measurements.

Informally, and without limitation to a particular model or framework of understanding, the reasons underlying this potential advantage may be understood by considering that a wall approaching the transmitting electrode has a different effect on the measurement system than a wall approaching the sensing electrode to the same degree. As a (relatively high-impedance) wall approaches the transmitting electrode 803, the transmission of current to ground electrode 805 will be correspondingly impeded. To maintain constant current transmission, the voltage at the transmission electrode will need to rise. The transmitting electrode being at one extreme of the electrical field's potential gradient, it will always have the maximum voltage, compared to the passive sensing electrode 804.

The passive sensing electrode 804 will also measure an increase in voltage-one which is roughly proportional to the maximum voltage gradient increase established at the transmitting electrode. Insofar, however, as this increase is no more than proportional, the difference of V₁-V₂ will still tend to increase. Besides, when the wall is closer to the transmitting electrode, the sensing electrode will increase sub-proportionally (leading to an even greater increase in V₁-V₂), since it is experiencing corresponding less of a change in its nearest environment.

No converse effect like this is expected for an impedance increase near the sensing electrode. Naturally, as much as the passive sensing electrode experiences a direct impedance increase due to proximity of the wall, there will be somewhat of a second “lobe” of sensitivity around it as shown in FIG. 8D (and this lobe represents a deviation from sphericity of the sensitivity function). But it will, in general, take much greater proximity to the sensing electrode to achieve a given increase in V₁-V₂ (if it is indeed possible); at least because the sensing electrode is not configured to drive an overall gradient increase like the transmitting electrode can.

These qualitative considerations at least partially account for why local impedance (as defined through the derivation above) enhances sphericity of the sensitivity function relative to, for example, the bipolar electrode arrangement of FIGS. 8A-8B, wherein about the same current flows into one electrode as flows out of the other. Quantitative calculations of comparative sensitivity (for example as shown in FIG. 8B compared to FIG. 8D) show that the difference is potentially quite pronounced.

It should be noted that the closer the passive sensing electrode 804 is, physically, to the transmitting electrode 803, the more the local impedance A (block 821) is decreased. In effect, increasing proximity of the passive sensing electrode 804 to the transmitting electrode 803 causes more and more of the total impedance between the transmission electrode 803 and ground 805 to be assigned to the common (C) component (block 823), leaving less for the local impedance component (block 821). The practical effect of this is a reduced sensitivity range in terms of distance. Whatever structures exist relatively far from (and at a relatively similar distance to) both the sensing and transmission electrodes affects them about the same, and also weaker as distance increases, so that they do not contribute much to the voltage difference V₁-V₂ used in calculating local impedance.

### Local Impedance Measurement Configurations

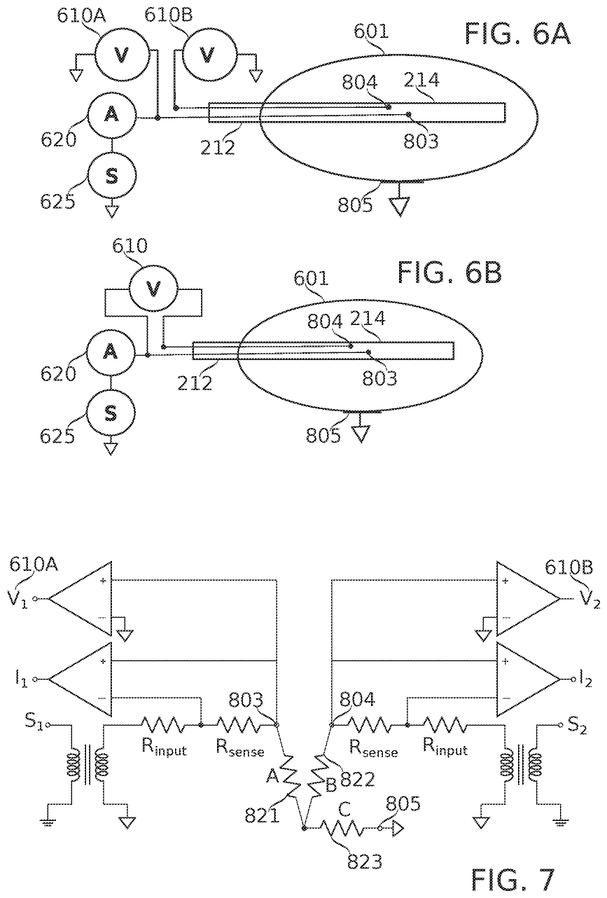

Reference is now made to FIGS. 6A-6B, which schematically illustrate two alternative methods of making electrical measurements in accordance with the determination of a local impedance as described in relation to FIGS. 8C-8D, according to some embodiments of the present disclosure.

In both of FIGS. 6A-6B, an intralumenal probe 214 of a catheter 212 is inserted to a body cavity 601, carrying a plurality of electrodes including 803, 804, with electrode 803 being used as the transmitting electrode, and electrode 804 being used as the sensing electrode. Electrode 805 is being used as a ground electrode. Also, in each case, current 620 (circled A) is being measured as it is driven through transmitting electrode 803 from an AC electrical source 625 (circled S). In FIG. 6A, voltages 610A, 610B (circled Vs) are being measured relative to each of electrodes 803, 804 and ground. The difference of these voltages is equivalent to voltage 610 of FIG. 8B, measured directly between electrodes 804, 803.

Reference is now made to FIG. 7, which schematically illustrates a more detailed measurement circuit corresponding to an implementation of the measurement configuration of FIG. 6A, according to some embodiments of the present disclosure. Voltages V₁ and V₂ are each being measured relative to ground, corresponding to voltages 610A, 610B of FIG. 6A. Resistors A, B, C correspond to impedances 821, 822, 823 described in relation to FIG. 8C. In the example shown, raw measurement I₁ is a voltage measurement; however, it is measured from the overall circuit so that its value is a proportional indicator according to Ohm's law of the current 811 being driven through electrode 803. Current 811 is obtained by dividing I₁ by the known resistance value of Rₛₑₙₛₑ. The current is being driven by driver circuit S₁.

Optionally, electrodes 803, 804 are simultaneously operated with their roles in transmission/sensing reversed, and electrode 804 being driven by driver circuit S₂, with its own driving current being sensed thorugh raw measurement I₂. The driving frequencies of S₁ and S₂ are selected so that their respective effects on circuit measurements can be decomposed mathematically and/or by appropriate filtering circuitry, and attributed to the appropriate subsystem of the overall measurement circuit. This arrangement is optionally duplicated to a larger number of transmission electrodes and driving frequencies, with any of the other electrodes being optionally selected to act as a sensing electrode as well as or alternatively to acting as a transmitting electrode.

### General

As used herein with reference to quantity or value, the term “about” means “within ±10% of”.

The terms “comprises”, “comprising”, “includes”, “including”, “having” and their conjugates mean: “including but not limited to”.

The term “consisting of” means: “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

The words “example” and “exemplary” are used herein to mean “serving as an example, instance or illustration”. Any embodiment described as an “example” or “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the present disclosure may include a plurality of “optional” features except insofar as such features conflict.

As used herein the term “method” refers to manners, means, techniques and procedures for accomplishing a given task including, but not limited to, those manners, means, techniques and procedures either known to, or readily developed from known manners, means, techniques and procedures by practitioners of the chemical, pharmacological, biological, biochemical and medical arts.

As used herein, the term “treating” includes abrogating, substantially inhibiting, slowing or reversing the progression of a condition, substantially ameliorating clinical or aesthetical symptoms of a condition or substantially preventing the appearance of clinical or aesthetical symptoms of a condition.

Throughout this application, embodiments may be presented with reference to a range format. It should be understood that the description in range format is merely for convenience and brevity and should not be construed as an inflexible limitation on the scope of descriptions of the present disclosure. Accordingly, the description of a range should be considered to have specifically disclosed all the possible subranges as well as individual numerical values within that range. For example, description of a range such as “from 1 to 6” should be considered to have specifically disclosed subranges such as “from 1 to 3”, “from 1 to 4”, “from 1 to 5”, “from 2 to 4”, “from 2 to 6”, “from 3 to 6”, etc.; as well as individual numbers within that range, for example, 1, 2, 3, 4, 5, and 6. This applies regardless of the breadth of the range.

Whenever a numerical range is indicated herein (for example “10-15”, “10 to 15”, or any pair of numbers linked by these another such range indication), it is meant to include any number (fractional or integral) within the indicated range limits, including the range limits, unless the context clearly dictates otherwise. The phrases “range/ranging/ranges between” a first indicate number and a second indicate number and “range/ranging/ranges from” a first indicate number “to”, “up to”, “until” or “through” (or another such range-indicating term) a second indicate number are used herein interchangeably and are meant to include the first and second indicated numbers and all the fractional and integral numbers therebetween.

Although descriptions of the present disclosure are provided in conjunction with specific embodiments, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

It is appreciated that certain features which are, for clarity, described in the present disclosure in the context of separate embodiments, may also be provided in combination in a single embodiment. Conversely, various features, which are, for brevity, described in the context of a single embodiment, may also be provided separately or in any suitable subcombination or as suitable in any other described embodiment of the present disclosure. Certain features described in the context of various embodiments are not to be considered essential features of those embodiments, unless the embodiment is inoperative without those elements.

What is claimed is:

1. A method of estimating a proximity of a wall of an intra-body lumen to a first electrode at a first position within the body lumen, the method comprising:
generating an electrical field by transmitting a current from the first electrode to a ground electrode;
measuring a voltage difference of the electrical field between the first electrode and a second electrode at a second position within the body lumen;
calculating a measure of local impedance for a region around the first electrode, using:
the voltage difference measured between the first and second electrodes and
a measurement of the current between the first electrode and the ground; and
converting the measure of local impedance to an estimate of proximity of the wall of the intra-body lumen to the first electrode.

2. The method of claim 1, wherein the measure of local impedance is proportional to the voltage difference between the first and second electrodes.

3. The method of claim 1, wherein the measure of local impedance is inversely proportional to an amount of current transmitted from the first electrode.

4. The method of claim 1, wherein less than 10% of current flowing from the first electrode flows through the second electrode.

5. The method of claim 1, wherein the ground electrode is at least 5 cm away from each of the first and second electrodes.

6. The method of claim 1, wherein the ground electrode and the first and second electrodes are all on the same probe.

7. The method of claim 1, wherein the measure of local impedance is at least 5× more sensitive to the wall at a distance of 5 mm from the first electrode than at a distance of 5 mm from the second electrode.

8. The method of claim 1, comprising also performing the generating, measuring, calculating, and converting as recited for the first electrode and second electrode, with the first electrode in roles as recited for the second electrode and the second electrode in roles as recited for the first electrode, wherein the first and second electrodes transmit their respective currents at different respective frequencies.

9. The method of claim 1, wherein the current transmitted from the first electrode to the ground electrode is restricted from flowing through said second electrode by an impedance at least ten times larger than the impedance between the first electrode and the ground electrode.

10. The method of claim 1, wherein the converting comprises applying a sensitivity function describing the measure of local impedance as a function of distance to a nearest wall portion.

11. The method of claim 10, wherein the sensitivity function is determined based on a distance between the first and second electrodes, with the sensitivity range increasing as the distance becomes larger.

12. The method of claim 1, comprising repeating the voltage measuring, calculating, and converting to produce a plurality of estimates of proximity of the wall for each of a corresponding plurality of positions of the first electrode; and comprising mapping a shape of the wall, using the estimated proximity of the wall in each of the plurality of positions of the first electrode.

13. The method of claim 12, wherein the mapping comprises:
defining an array of voxels representing volumes of a three-dimensional space;
for each estimate of the proximity of the wall to the first electrode, accumulating evidence of presence of a wall within a substantially spherical shell region represented by some voxels of the array of voxels;
wherein the shell region is centered on a position of the first electrode, and has a radius corresponding to the estimate of the proximity of the wall to the first electrode.

14. The method of claim 13, wherein the shell region has a predetermined thickness.

15. The method of claim 13, wherein the mapping comprises analyzing a distribution of wall presence evidence accumulated in the array of voxels, to determine positions of the wall consistent with the accumulated wall presence evidence.

16. The method of claim 13, wherein the mapping comprises
for each estimate of the proximity of the wall, accumulating evidence of absence of a wall within a substantially spherical region represented by some voxels of the array of voxels;
wherein the spherical region is centered on a position of the first electrode, and has a radius corresponding to the estimate of the proximity of the wall and the first electrode.

17. The method of claim 1, wherein the converting comprises comparing the measure of local impedance to a local impedance measured while the first electrode is located at least 10 mm away from any wall of the intra-body lumen.

18. The method of claim 1, comprising performing the generating, the measuring, and the calculating while the first electrode is at a first position at least 10 mm away from the wall, and then while the first electrode is at a second position between 5 and 9 mm away from the wall; and wherein the estimating of the second position between 5 and 9 mm away from the wall is performed without using measurements obtained by the first electrode at a position less than 5 mm away from the wall.

19. A system for estimating a proximity of a wall of an intra-body lumen to a first electrode at a first position within the intra-body lumen, the system comprising:
a ground electrode;
at least one probe sized and configured to be positioned in the intra-body lumen, the at least one probe comprising the first electrode and at least a second electrode;
a parameter measuring device, configured to generate an electrical field by transmitting a current from the first electrode to a ground electrode;
a measuring device, configured to measure the current, and to measure a voltage difference of the electrical field between the first electrode and the second electrode, the second electrode being positioned at a second position within the intra-body lumen;
a processor and a memory storing processor instructions, wherein the processor instructions instruct the processor to calculate a measure of local impedance for a region around the first electrode, using:
the voltage difference measured between the first and second electrodes, and
the measured current between the first electrode and the ground electrode.

20. The system of claim 19, wherein the processor instructions further instruct the processor to convert the measure of local impedance to an estimate of proximity of the wall of the intra-body lumen to the first electrode.

21. The system of claim 20, wherein the measure of local impedance is at least 5× more sensitive to the wall at a distance of 5 mm from the first electrode than at a distance of 5 mm from the second electrode.

22. The system of claim 20, wherein the processor also is instructed to calculate and convert as recited for the first electrode and second electrode, with the first electrode in roles as recited for the second electrode and the second electrode in roles as recited for the first electrode; wherein the first and second electrodes transmit their respective currents at different respective frequencies.

23. The system of claim 20, wherein the processor applies a sensitivity function describing the measure of local impedance as a function of distance to a nearest wall portion to convert the measure of local impedance to the estimate of proximity.

24. The system of claim 23, wherein the sensitivity function is determined based on a distance between the first and second electrodes, with the sensitivity range increasing as the distance becomes larger.

25. The system of claim 20, wherein the system is configured to repeat the voltage measuring, the calculation, and the conversion, to produce a plurality of estimates of proximity of the wall for each of a corresponding plurality of positions of the first electrode; and the instruction instruct the processor to map a shape of the wall, using the estimated proximity of the wall in each of the plurality of positions of the first electrode.

26. The system of claim 25, wherein the processor is instructed to map the shape of the wall by:
defining an array of voxels representing volumes of a three-dimensional space; and
for each estimate of the proximity of the wall to the first electrode, accumulating evidence of presence of a wall within a substantially spherical shell region represented by some voxels of the array of voxels;
wherein the shell region is centered on a position of the first electrode, and has a radius corresponding to the estimate of the proximity of the wall to the first electrode.

27. The system of claim 26, wherein the shell region has a predetermined thickness.

28. The system of claim 26, wherein the processor is instructed to map the shape of the wall by analyzing a distribution of wall presence evidence accumulated in the array of voxels, to determine positions of the wall consistent with the accumulated wall presence evidence.

29. The system of claim 26, wherein the processor is instructed to map the shape of the wall by:
for each estimate of the proximity of the wall, accumulating evidence of absence of a wall within a substantially spherical region represented by some voxels of the array of voxels;
wherein the spherical region is centered on a position of the first electrode, and has a radius corresponding to the estimate of the proximity of the wall and the first electrode.

30. The system of claim 20, wherein the processor is instructed to perform the conversion by comparing the measure of local impedance to a local impedance measured while the first electrode is located at least 10 mm away from any wall of the intra-body lumen.

31. The system of claim 20, wherein the processor is instructed to calculate the measure of local impedance using a measurement measured while the first electrode is at a first position at least 10 mm away from the wall, and another measurement measured while the first electrode is at a second position between 5 and 9 mm away from the wall; and to estimate of the second position between 5 and 9 mm away from the wall without using measurements obtained by the first electrode at a position less than 5 mm away from the wall.

32. The system of claim 19, wherein the measure of local impedance is proportional to the voltage difference between the first and second electrodes.

33. The system of claim 19, wherein the measure of local impedance is inversely proportional to an amount of current transmitted from the first electrode.

34. The system of claim 19, wherein less than 10% of current flowing from the first electrode flows through the second electrode.

35. The system of claim 19, wherein the ground electrode is configured to be positioned at least 5 cm away from each of the first and second electrodes.

36. The system of claim 19, wherein the ground electrode and the first and second electrodes are all on the same probe of the at least one probe.

37. The system of claim 19, wherein the current transmitted from the first electrode to the ground electrode is restricted from flowing through said second electrode by an impedance at least ten times larger than the impedance between the first electrode and the ground electrode.
